(19) United States
(12) Patent Application Publication
(10) Pub. No.: US 2023/0167308 A1
(43) Pub. Date: Jun. 1, 2023

(54) LEAD-SEQUESTRATION MATERIAL FOR PEROVSKITE DEVICES

(71) Applicant: CubicPV Inc., Dallas, TX (US)

(72) Inventors: Michael D. Irwin, Heath, TX (US); Minh Tu Nguyen, Dallas, TX (US)

(21) Appl. No.: 18/070,257

(22) Filed: Nov. 28, 2022

Related U.S. Application Data
(60) Provisional application No. 63/283,514, filed on Nov. 28, 2021.

(51) Int. Cl. C09D 5/00; C09D 7/63; C09D 7/40

(52) U.S. Cl. CPC C09D 5/006; C09D 7/63; C09D 7/68; C09D 7/67; C09D 7/69; C09D 7/70

(57) ABSTRACT

A composition that includes a binding material and a lead-sequestration compound attached to the binding material, the lead-sequestration compound including one or more lead binding groups selected from the group consisting of: a carboxylate, a phosphate, a sulfide, a sulfate, and any combination thereof.

### CROSS-REFERENCE TO RELATED APPLICATIONS

This application claims priority to U.S. Provisional Patent Application No. 63/283,514 filed Nov. 28, 2021 and entitled “LEAD-SEQUESTRATION MATERIAL FOR PEROVSKITE DEVICES”, the contents of which are incorporated by reference herein in its entirety.

### BACKGROUND

Use of photovoltaics (PVs) to generate electrical power from solar energy or radiation may provide many benefits, including, for example, a power source, low or zero emissions, power production independent of the power grid, durable physical structures (no moving parts), stable and reliable systems, modular construction, relatively quick installation, safe manufacture and use, and good public opinion and acceptance of use. Perovskite photovoltaics, as emerging high-efficiency and low-cost photovoltaic technology, face obstacles like lead leakage.

PVs may incorporate layers of perovskite materials as photoactive layers that generate electric power when exposed to light. Some perovskite photovoltaics include lead and other metal ions that may be susceptible to leakage. Therefore, improvements to lead and metal ion sequestration techniques and materials are desirable.

### SUMMARY

According to certain embodiments, a perovskite material device comprises: a lead-sequestration compound comprising one or more lead binding groups selected from the group consisting of: an oxide, a hydroxide, an amine, an amide, an ammonium, an acetylacetone, an acetylacetonate, a carboxylate, a carboxylic acid, an aldehyde, an ester, an ether, a phosphine, a phosphinate, a phosphonate, a phosphate, a sulfide, a sulfate, and any combination thereof.

According to certain embodiments, a method comprises: preparing a substrate; depositing a precursor ink comprising a lead-sequestration material onto the substrate, wherein the lead-sequestration material comprises: a lead-sequestration compound comprising one or more lead binding groups selected from the group consisting of: an oxide, a hydroxide, an amine, an amide, an ammonium, an acetylacetone, an acetylacetonate, a carboxylate, a carboxylic acid, an aldehyde, an ester, an ether, a phosphine, a phosphinate, a phosphonate, a phosphate, a sulfide, a sulfate, and any combination thereof, and a binding material; and drying the lead-sequestration precursor ink to form a lead-sequestration material layer.

According to certain embodiments, composition comprises: a binding material; and a lead-sequestration compound attached to the binding material, the lead-sequestration compound comprising one or more lead binding groups selected from the group consisting of: an oxide, a hydroxide, an amine, an amide, an ammonium, an acetylacetone, an acetylacetonate, a carboxylate, a carboxylic acid, an aldehyde, an ester, an ether, a phosphine, a phosphinate, a phosphonate, a phosphate, a sulfide, a sulfate, and any combination thereof.

### BRIEF DESCRIPTION OF THE DRAWINGS

FIG. 1 is a schematic diagram illustrating components of a photovoltaic device according to some embodiments of the present disclosure.

FIG. 2 is a schematic diagram illustrating components of a photovoltaic device according to some embodiments of the present disclosure.

FIG. 3 is a stylized diagram illustrating an example of lead sequestration mechanics according to some embodiments of the present disclosure.

FIG. 4 is a schematic diagram illustrating components of a photovoltaic device according to some embodiments of the present disclosure.

FIG. 5 is a schematic diagram illustrating components of a photovoltaic device according to some embodiments of the present disclosure.

FIG. 6 is a schematic diagram illustrating components of a photovoltaic device according to some embodiments of the present disclosure.

FIG. 7 is a schematic diagram illustrating components of a photovoltaic device according to some embodiments of the present disclosure.

FIG. 8 is a schematic diagram illustrating components of a photovoltaic device according to some embodiments of the present disclosure.

FIG. 9 is a schematic diagram illustrating components of a photovoltaic device according to some embodiments of the present disclosure.

FIGS. 10A and 10B are diagrams illustrating the chemical structures of lead sequestration ethylenediaminetetraacetic acid (EDTA) and EDTA derivatives according to some embodiments of the present disclosure.

FIGS. 11A-11E are diagrams illustrating the chemical structures of EDTA derivatives according to some embodiments of the present disclosure.

FIGS. 12A-12F are diagrams illustrating the chemical structures of organophosphates according to some embodiments of the present disclosure.

FIGS. 13A-13C illustrate organophosphate lead-sequestration compounds according to some embodiments of the present disclosure.

FIGS. 14A and 14B illustrate organophosphate lead-sequestration compounds according to some embodiments of the present disclosure.

FIGS. 15A and 15B illustrate organophosphate lead-sequestration compounds according to some embodiments of the present disclosure.

FIGS. 16A-16C organosulfate lead-sequestration compounds according to some embodiments of the present disclosure.

FIGS. 17A and 17B illustrate organosulfate lead-sequestration compounds according to some embodiments of the present disclosure.

FIGS. 18A and 18B illustrate organosulfate lead-sequestration compounds according to some embodiments of the present disclosure.

FIGS. 19A, 19B, 20, and 21A-21E illustrate lead-sequestration compounds attached to inorganic materials according to some embodiments of the present disclosure.

FIGS. 22A-22D illustrate lead-sequestration compounds attached to silica gels according to some embodiments of the present disclosure.

FIGS. 23A-23B, 24A-24E, 25A-25C and 26 illustrate lead-sequestration compounds attached to polymers according to some embodiments of the present disclosure.

FIG. 27 illustrates the structure of cross-linked porous resin (CPRs) according to some embodiments of the present disclosure.

FIG. 28 illustrates lead-sequestration compounds attached to CPRs according to some embodiments of the present disclosure.

FIG. 29 is a stylized diagram showing components of an example PV device according to some embodiments of the present disclosure.

FIG. 30 is a stylized diagram showing components of an example device according to some embodiments of the present disclosure.

FIG. 31 illustrates x-ray diffraction patterns of perovskites materials according to some embodiments of the present disclosure.

FIG. 32 is a schematic diagram illustrating components of a photovoltaic device according to some embodiments of the present disclosure.

FIG. 33 is a schematic diagram illustrating components of a photovoltaic device according to some embodiments of the present disclosure.

### DETAILED DESCRIPTION OF PREFERRED EMBODIMENTS

The features and advantages of the present disclosure will be readily apparent to those skilled in the art. While numerous changes may be made by those skilled in the art, such changes are within the spirit of the invention.

The present disclosure relates generally to compositions of matter, apparatus and methods of use of materials in photovoltaic cells in creating electrical energy from solar radiation. Some or all of materials in accordance with some embodiments of the present disclosure may also advantageously be used in any organic or other electronic device, with some examples including, but not limited to: batteries, field-effect transistors (FETs), light-emitting diodes (LEDs), non-linear optical devices, transistors, ionizing radiation detectors, memristors, capacitors, rectifiers, and/or rectifying antennas.

In some embodiments, the present disclosure may provide PV and other similar devices (e.g., batteries, hybrid PV batteries, multi junction PVs, FETs, LEDs, x-ray detectors, gamma ray detectors, photodiodes, CCDs, etc.). Such devices may in some embodiments include improved active material, interfacial layers (IFLs), and/or one or more perovskite materials. A perovskite material may be incorporated into various of one or more aspects of a PV or other device. Perovskite materials according to various embodiments are discussed in greater detail below.

Photovoltaic Cells and Other Electronic Devices

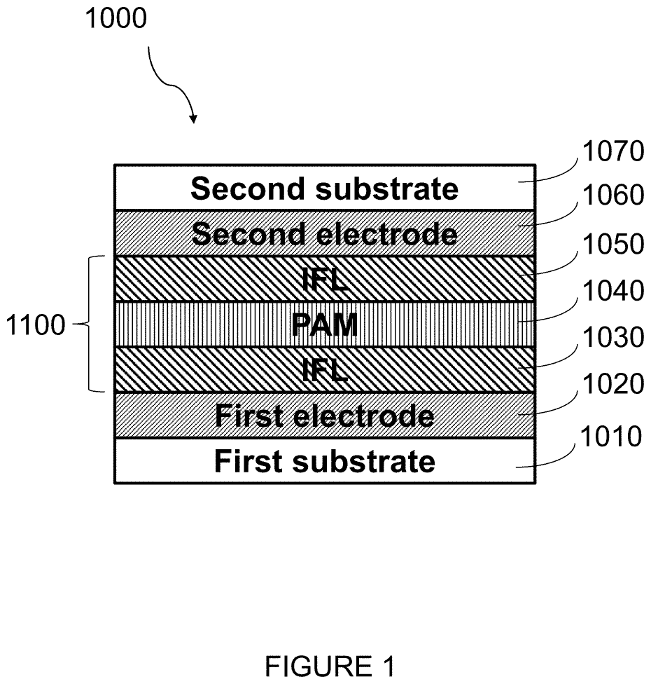

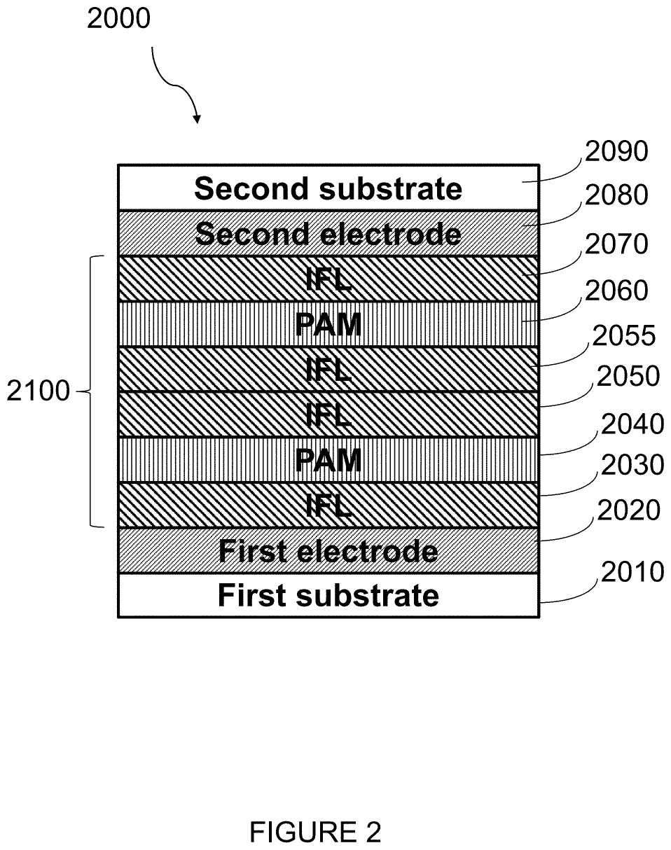

Some PV embodiments may be described by reference to the illustrative depictions of a perovskite material device as shown in FIG. 1. An example PV architecture according to some embodiments may be substantially of the form substrate-anode-IFL-active layer-IFL-cathode. The active layer of some embodiments may be photoactive, and/or it may include photoactive material. Other layers and materials may be utilized in the cell as is known in the art. Furthermore, it should be noted that the use of the term “active layer” is in no way meant to restrict or otherwise define, explicitly or implicitly, the properties of any other layer—for instance, in some embodiments, either or both IFLs may also be active insofar as they may be semiconducting. In particular, referring to FIG. 1, a stylized generic PV cell 1000 is depicted, illustrating the highly interfacial nature of some layers within the PV. The PV 1000 represents a generic architecture applicable to several PV devices, such as perovskite material PV embodiments. The PV cell 1000 includes a transparent substrate layers 1010 and 1070, which may be glass (or a material similarly transparent to solar radiation) which allows solar radiation to transmit through the layer. The transparent layer of some embodiments may also be referred to as a superstrate or substrate, and it may comprise any one or more of a variety of rigid or flexible materials such as: glass, polyethylene, polypropylene, polycarbonate, polyimide, PMMA, PET, PEN, Kapton, or quartz. In general, the term substrate is used to refer to material upon which the device is deposited during manufacturing. The photoactive (PAM) layer 1040 may be composed of electron donor or p-type material, and/or an electron acceptor or n-type material, and/or an ambipolar semiconductor, which exhibits both p- and n-type material characteristics, and/or an intrinsic semiconductor which exhibits neither n-type or p-type characteristics. Photoactive layer 1040 may be a perovskite material as described herein, in some embodiments. The active layer or, as depicted in FIG. 1, the PAM layer 1040, is sandwiched between two electrically conductive electrode layers 1020 and 1060. In FIG. 1, the electrode layer 1020 may be a transparent conductor such as a tin-doped indium oxide (ITO material) or other material as described herein. In some embodiments, the second electrode 1060 may be transparent. The second electrode layer 1060 may be an aluminum material or other metal, or other conductive materials such as carbon. Other materials may be used as is known in the art. The cell 1100 also includes an interfacial layer (IFL) 1030, shown in the example of FIG. 1. The IFL may assist in charge separation. In other embodiments, the IFL 1030 may comprise a multi-layer IFL. For example, a perovskite material device may contain zero, one, two, three, four, five, or more interfacial layers (such as the example device of FIG. 2, which contains four interfacial layers 2030, 2050, 2055, and 2070). There also may be an IFL 1050 adjacent to the second electrode 1060. In some embodiments, the IFL 1050 adjacent to the second electrode 1060 may also or instead comprise a multi-layer IFL. An IFL according to some embodiments may be semiconducting in character and may be either intrinsic, ambipolar, p-type, or n-type, or it may be dielectric in character. In some embodiments, the IFL on the cathode side of the device (e.g., IFL 1050 as shown in FIG. 1) may be p-type, and the IFL on the anode side of the device (e.g., IFL 1030 as shown in FIG. 1) may be n-type. In other embodiments, however, the cathode-side IFL may be n-type and the anode-side IFL may be p-type. The cell 1100 may be attached to electrical leads by electrodes 1060 and 1020 and a discharge unit, such as a battery, motor, capacitor, electric grid, or any other electrical load.

According to various embodiments, devices may optionally include an interfacial layer between any two other layers and/or materials, although devices need not contain any interfacial layers. For example, a perovskite material device may contain zero, one, two, three, four, five, or more interfacial layers (such as the example device of FIG. 2, which contains four interfacial layers 2030, 2050, 2055, and 2070). An interfacial layer may include any suitable material for enhancing charge transport and/or collection between two layers or materials; it may also help prevent or reduce the likelihood of charge recombination once a charge has been transported away from one of the materials adjacent to the interfacial layer. An interfacial layer may additionally physically and electrically homogenize its substrates to create variations in substrate roughness, dielectric constant, adhesion, creation or quenching of defects (e.g., charge traps, surface states). Suitable interfacial materials may include any one or more of: Ag; Al; Au; B; Bi; Ca; Cd; Ce; Co; Cu; Fe; Ga; Ge; H; In; Mg; Mn; Mo; Nb; Ni; Pt; Sb; Sc; Si; Sn; Ta; Ti; V; W; Y; Zn; Zr; carbides of any of the foregoing metals (e.g., SiC, Fe₃C, WC, VC, MoC, NbC); silicides of any of the foregoing metals (e.g., Mg₂Si, SrSi₂, Sn₂Si); oxides of any of the foregoing metals (e.g., alumina, silica, titania, SnO₂, ZnO, NiO, ZrO₂, HfO₂), include transparent conducting oxides (“TCOs”) such as indium tin oxide, aluminum doped zinc oxide (AZO), cadmium oxide (CdO), and fluorine doped tin oxide (FTO); sulfides of any of the foregoing metals (e.g., CdS, MoS₂, SnS₂); nitrides of any of the foregoing metals (e.g., GaN, Mg₃N₂, TiN, BN, Si₃N₄); selenides of any of the foregoing metals (e.g., CdSe, FeS₂, ZnSe); tellurides of any of the foregoing metals (e.g., CdTe, TiTe₂, ZnTe); phosphides of any of the foregoing metals (e.g., InP, GaP, GaInP); arsenides of any of the foregoing metals (e.g., CoAs₃, GaAs, InGaAs, NiAs); antimonides of any of the foregoing metals (e.g., AlSb, GaSb, InSb); halides of any of the foregoing metals (e.g., CuCl, CuI, BiI₃); pseudohalides of any of the foregoing metals (e.g., CuSCN, AuCN, Fe(SCN)₂); carbonates of any of the foregoing metals (e.g., CaCO₃, Ce₂(CO₃)₃); functionalized or non-functionalized alkyl silyl groups; graphite; graphene; fullerenes; carbon nanotubes; any mesoporous material and/or interfacial material discussed elsewhere herein; and combinations thereof (including, in some embodiments, bilayers, trilayers, or multi-layers of combined materials). In some embodiments, an interfacial layer may include perovskite material. Further, interfacial layers may comprise doped embodiments of any interfacial material mentioned herein (e.g., Y-doped ZnO, N-doped single-wall carbon nanotubes). Interfacial layers may also comprise a compound having three of the above materials (e.g., CuTiO₃, Zn₂SnO₄) or a compound having four of the above materials (e.g., CoNiZnO). The materials listed above may be present in a planar, mesoporous or otherwise nano-structured form (e.g. rods, spheres, flowers, pyramids), or aerogel structure. U.S. Pat. No. 11,171,290, incorporated herein by reference in its entirety, describes additional types of interfacial layers and suitable materials for IFLs of the present disclosure.

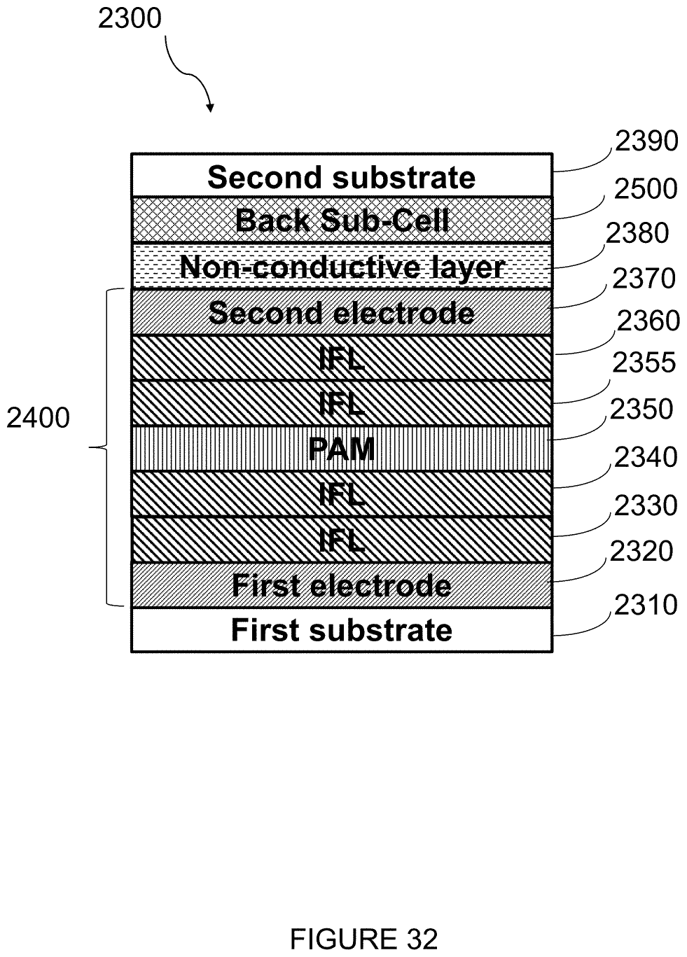

Additionally, some perovskite material PV cells may include so called “tandem” PV devices having more than one perovskite photoactive layer. An example of a tandem PV device is shown in FIG. 2, which includes two photoactive materials 2040 and 2060. In some embodiments, both photoactive materials 2040 and 2060 of FIG. 2 may be perovskite materials. FIG. 2 depicts a two-terminal tandem PV device 2000, i.e., the two photoactive materials are integrated together into a single monolithic PV cell. In such tandem PV cells an interfacial layer between the two photoactive layers, such as IFL 2050 and 2055 of FIG. 2 may comprise a multi-layer, or composite IFL. In some embodiments, the layers sandwiched between the two photoactive layers of a tandem PV device may include an electrode layer. In some embodiments, a tandem PV device may be a four-terminal device, such as the device shown in FIG. 32. Four-terminal tandem PV devices may include two sub-cells that are electrically independent from each other but optically coupled.

A two-terminal tandem PV device may include the following layers, listed in order from either top to bottom or bottom to top: a first substrate, a first electrode, a first interfacial layer, a first perovskite material, a second interfacial layer, a second electrode, a third interfacial layer, a second perovskite material, a fourth interfacial layer, and a third electrode. In some embodiments, the first and third interfacial layers may be hole transporting interfacial layers and the second and fourth interfacial layers may be electron transporting interfacial layers. In other embodiments, the first and third interfacial layers may be electron transporting interfacial layers and the second and fourth interfacial layers may be hole transporting interfacial layers. In yet other embodiments, the first and fourth interfacial layers may be hole transporting interfacial layers and the second and third interfacial layers may be electron transporting interfacial layers. In other embodiments, the first and fourth interfacial layers may be electron transporting interfacial layers and the second and third interfacial layers may be hole transporting interfacial layers.

In tandem PV devices, the first and second perovskite materials may have different band gaps. In some embodiments, the first perovskite material may be formamidinium lead bromide (FAPbBr₃) and the second perovskite material may be formamidinium lead iodide (FAPbI₃). In other embodiments, the first perovskite material may be methylammonium lead bromide (MAPbBr₃) and the second perovskite material may be formamidinium lead iodide (FaPbI₃). In other embodiments, the first perovskite material may be methylammonium lead bromide (MAPbBr₃) and the second perovskite material may be methylammonium lead iodide (MAPbI₃).

Perovskite Material

A perovskite material may be incorporated into one or more aspects of a PV or other device. A perovskite material according to some embodiments may be of the general formula C_{w}M_{y}X_{z}, where: C comprises one or more cations (e.g., an amine, ammonium, phosphonium a Group 1 metal, a Group 2 metal, and/or other cations or cation-like compounds); M comprises one or more metals (examples including Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr); X comprises one or more anions; and w, y, and z represent real numbers between 1 and 20. In some embodiments, C may include one or more organic cations. In some embodiments, each organic cation C may be larger than each metal M, and each anion X may be capable of bonding with both a cation C and a metal M.

In certain embodiments, C may include an ammonium, an organic cation of the general formula [NR₄]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

In certain embodiments, C may include a formamidinium, an organic cation of the general formula [R₂NCRNR₂]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., imidazole, benzimidazole, pyrimidine, (azolidinylidenemethyl)pyrrolidine, triazole); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

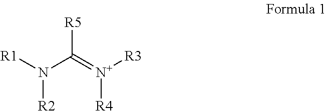

Formula 1 illustrates the structure of a formamidinium cation having the general formula of [R₂NCRNR₂]⁺ as described above. Formula 2 illustrates examples structures of several formamidinium cations that may serve as a cation “C” in a perovskite material.

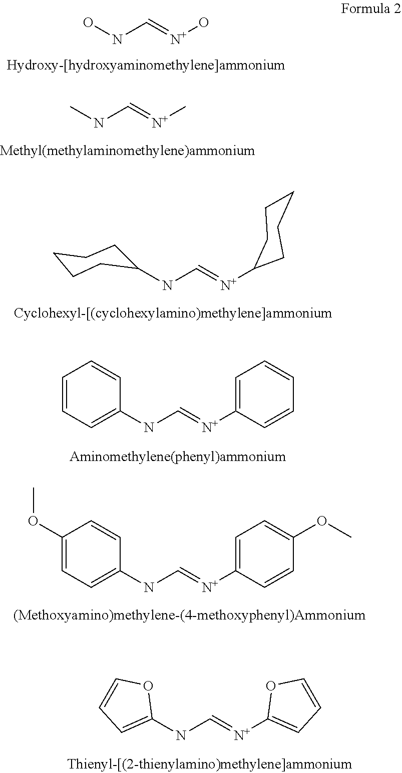

In certain embodiments, C may include a guanidinium, an organic cation of the general formula [(R₂N)₂C═NR₂]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., octahydropyrimido[1,2-a]pyrimidine, pyrimido[1,2-a]pyrimidine, hexahydroimidazo[1,2-a]imidazole, hexahydropyrimidin-2-imine); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

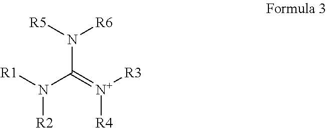

Formula 3 illustrates the structure of a guanidinium cation having the general formula of [(R₂N)₂C═NR₂]⁺ as described above. Formula 4 illustrates examples of structures of several guanidinium cations that may serve as a cation “C” in a perovskite material.

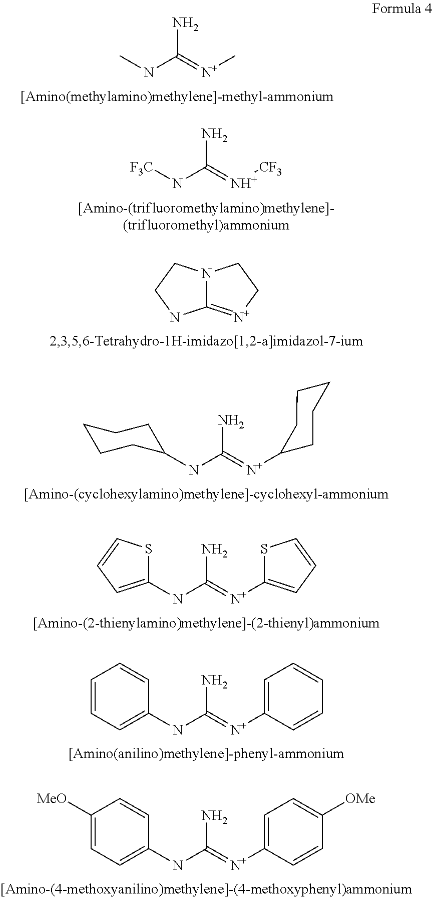

In certain embodiments, C may include an ethene tetramine cation, an organic cation of the general formula [(R₂N)₂C═C(NR₂)₂]⁺ where the R groups may be the same or different groups. Suitable R groups include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X=F, Cl, Br, or I; any aromatic group (e.g., phenyl, alkylphenl, alkoxyphenyl, pyridine, naphthalene); cyclic complexes where at least one nitrogen is contained within the ring (e.g., 2-hexahydropyrimidin-2-ylidenehexahydropyrimidine, octahydropyrazino[2,3-b]pyrazine, pyrazino[2,3-b]pyrazine, quinoxalino[2,3-b]quinoxaline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

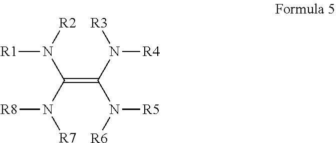

Formula 5 illustrates the structure of an ethene tetramine cation having the general formula of [(R₂N)₂C═C(NR₂)₂]⁺ as described above. Formula 6 illustrates examples of structures of several ethene tetramine ions that may serve as a cation “C” in a perovskite material.

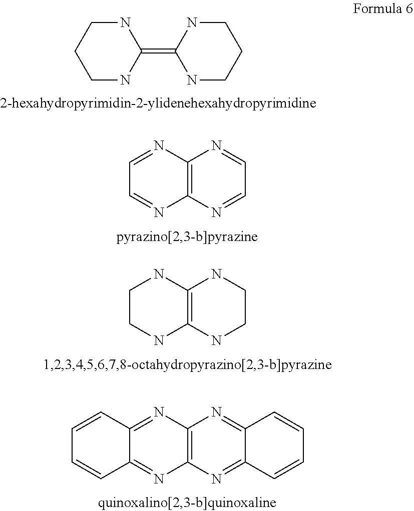

In certain embodiments, C may include an imidazolium cation, an aromatic, cyclic organic cation of the general formula [CRNRCRNRCR]⁺ where the R groups may be the same or different groups. Suitable R groups may include, but are not limited to: hydrogen, methyl, ethyl, propyl, butyl, pentyl group or isomer thereof; any alkane, alkene, or alkyne CxHy, where x=1-20, y=1-42, cyclic, branched or straight-chain; alkyl halides, CxHyXz, x=1-20, y=0-42, z=1-42, X═F, Cl, Br, or I; any aromatic group (e.g., phenyl, alkylphenl, alkoxyphenyl, pyridine, naphthalene); cyclic complexes where at least one nitrogen is contained within the ring (e.g., 2-hexahydropyrimidin-2-ylidenehexahydropyrimidine, octahydropyrazino[2,3-b]pyrazine, pyrazino[2,3-b]pyrazine, quinoxalino[2,3-b]quinoxaline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCxHy, where x=0-20, y=1-42.

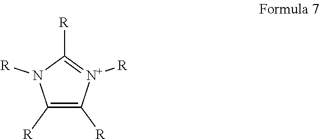

In some embodiments, X may include one or more halides. In certain embodiments, X may instead or in addition include a Group 16 anion. In certain embodiments, the Group 16 anion may be oxide, sulfide, selenide, or telluride. In certain embodiments, X may instead or in addition include one or more a pseudohalides (e.g., cyanide, cyanate, isocyanate, fulminate, thiocyanate, isothiocyanate, azide, tetracarbonylcobaltate, carbamoyldicyanomethanide, dicyanonitrosomethanide, dicyanamide, and tricyanomethanide).

By way of explanation, and without implying any limitations, exemplary embodiments of perovskite material having a formula C_{w}M_{y}X_{z}, are discussed below. In one embodiment, a perovskite material may comprise the empirical formula CMX₃ where: M comprises one of the aforementioned metals, C comprises one or more of the aforementioned cations, a Group 1 metal, a Group 2 metal, and/or other cations or cation-like compounds.

In another embodiment, a perovskite material may comprise the empirical formula C′M₂X₆ where: C′ comprises a cation with a 2+ charge including one or more of the aforementioned cations, diammonium butane, a Group 1 metal, a Group 2 metal, and/or other cations or cation-like compounds.

In another embodiment, a perovskite material may comprise the empirical formula C′MX₄ where: C′ comprises a cation with a 2+ charge including one or more of the aforementioned cations, diammonium butane, a Group 1 metal, a Group 2 metal, and/or other cations or cation-like compounds. In such an embodiment, the perovskite material may have a 2D structure. In one embodiment, a perovskite material may comprise the empirical formula C₃M₂X₉ where: C comprises one or more of the aforementioned cations, a Group 1 metal, a Group 2 metal, and/or other cations or cation-like compounds.

In one embodiment, a perovskite material may comprise the empirical formula CM₂X₇ where: C comprises one or more of the aforementioned cations, a Group 1 metal, a Group 2 metal, and/or other cations or cation-like compounds.

In one embodiment, a perovskite material may comprise the empirical formula C₂MX₄ where: C comprises one or more of the aforementioned cations, a Group 1 metal, a Group 2 metal, and/or other cations or cation-like compounds. Perovskite materials may also comprise mixed ion formulations where C, M, or X comprise two or more species. In some embodiments, the perovskite material may comprise two or more anions or three or more anions. In some embodiments, the perovskite material may comprise two more cations or three or more cations. In certain embodiments, the perovskite material may comprise two or more metals or three or more metals.

In one example, a perovskite material in the active layer may have the formulation CMX_{3-y}X′_{y} (0≥y≥3), where: C comprises one or more cations (e.g., an amine, ammonium, a Group 1 metal, a Group 2 metal, formamidinium, guanidinium, ethene tetramine, phosphonium, imidazolium, and/or other cations or cation-like compounds); M comprises one or more metals (e.g., Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr); and X and X′ comprise one or more anions. In one embodiment, the perovskite material may comprise CPbI_{3-y}Cl_{y}. In another example, a perovskite material in the active layer may have the formulation C₁₋ₓC′ₓMX₃(0≥x≥1), where C and C′ comprise one or more cations as discussed above. In another example, a perovskite material in the active layer may have the formulation CM_{1-z}M′_{z}X₃ (0≥z≥1), where M and M′ comprise one or more metals as discussed above. In one example, a perovskite material in the active layer may have the formulation C₁₋ₓC′ₓM_{1-z}M′_{z}X_{3-y}X′_{y} (0≥x≥1; 0≥y≥3; 0≥z≥1), where: C and C′ comprise one or more cations as discussed above; M and M′ comprise one or more metals as discussed above; and X and X′ comprise one or more anions as discussed above.

By way of explanation, and without implying any limitations, exemplary embodiments of perovskite material may be Cs_{0.1}FA_{0.9}Pb(I_{0.9}Cl_{0.1})₃; Rb_{0.1}FA_{0.9}Pb(I_{0.9}Cl_{0.1})₃Cs_{0.1}FA_{0.9}PbI₃; FAPb_{0.5}Sn_{0.5}I₃; FA_{0.83}Cs_{0.17}Pb(I_{0.6}Br_{0.4})₃; FA_{0.83}Cs_{0.12}Rb_{0.05}Pb(I_{0.6}Br_{0.4})₃ and FA_{0.85}MA_{0.15}Pb(I_{0.85}Br_{0.15})₃.

Composite Perovskite Material Device Design

In some embodiments, the present disclosure may provide composite design of PV and other similar devices (e.g., batteries, hybrid PV batteries, FETs, LEDs, nonlinear optics (NLOs), waveguides, etc.) including one or more perovskite materials. For example, one or more perovskite materials may serve as either or both of first and second active material of some embodiments. In more general terms, some embodiments of the present disclosure provide PV or other devices having an active layer comprising one or more perovskite materials. In such embodiments, perovskite material (that is, material including any one or more perovskite materials(s)) may be employed in active layers of various architectures. Furthermore, perovskite material may serve the function(s) of any one or more components of an active layer, discussed in greater detail below. In some embodiments, the same perovskite materials may serve multiple such functions, although in other embodiments, a plurality of perovskite materials may be included in a device, each perovskite material serving one or more such functions. In certain embodiments, whatever role a perovskite material may serve, it may be prepared and/or present in a device in various states. For example, it may be substantially solid in some embodiments. A solution or suspension may be coated or otherwise deposited within a device (e.g., on another component of the device such as a mesoporous, interfacial, charge transport, photoactive, or other layer, and/or on an electrode). Perovskite materials in some embodiments may be formed in situ on a surface of another component of a device (e.g., by vapor deposition as a thin-film solid). Any other suitable means of forming a layer comprising perovskite material may be employed.

In general, a perovskite material device may include a first electrode, a second electrode, and an active layer comprising a perovskite material, the active layer disposed at least partially between the first and second electrodes. In some embodiments, the first electrode may be one of an anode and a cathode, and the second electrode may be the other of an anode and cathode. An active layer according to certain embodiments may include any one or more active layer components, including any one or more of: charge transport material; liquid electrolyte; mesoporous material; photoactive material (e.g., a dye, silicon, cadmium telluride, cadmium sulfide, cadmium selenide, copper indium gallium selenide, gallium arsenide, germanium indium phosphide, semiconducting polymers, other photoactive materials)); and interfacial material. Any one or more of these active layer components may include one or more perovskite materials. In some embodiments, some or all of the active layer components may be in whole or in part arranged in sub-layers. For example, the active layer may comprise any one or more of: an interfacial layer including interfacial material; a mesoporous layer including mesoporous material; and a charge transport layer including charge transport material. Further, an interfacial layer may be included between any two or more other layers of an active layer according to some embodiments and/or between an active layer component and an electrode. Reference to layers herein may include either a final arrangement (e.g., substantially discrete portions of each material separately definable within the device), and/or reference to a layer may mean arrangement during construction of a device, notwithstanding the possibility of subsequent intermixing of material(s) in each layer. Layers may in some embodiments be discrete and comprise substantially contiguous material (e.g., layers may be as stylistically illustrated in FIG. 1).

In some embodiments, a perovskite material device may be a field effect transistor (FET). An FET perovskite material device may include a source electrode, drain electrode, gate electrode, dielectric layer, and a semiconductor layer. In some embodiments the semiconductor layer of an FET perovskite material device may be a perovskite material.

A perovskite material device according to some embodiments may optionally include one or more substrates. In some embodiments, either or both of the first and second electrode may be coated or otherwise disposed upon a substrate, such that the electrode is disposed substantially between a substrate and the active layer. The materials of composition of devices (e.g., substrate, electrode, active layer and/or active layer components) may in whole or in part be either rigid or flexible in various embodiments. In some embodiments, an electrode may act as a substrate, thereby negating the need for a separate substrate.

Furthermore, a perovskite material device according to certain embodiments may optionally include an anti-reflective layer or anti-reflective coating (ARC).

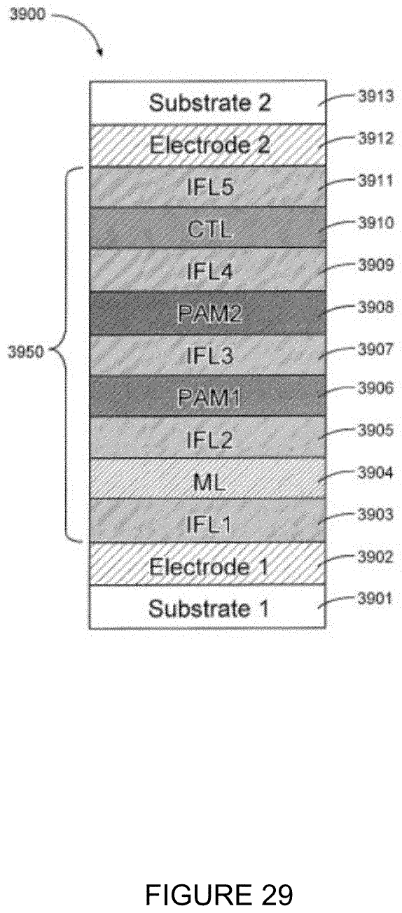

Description of some of the various materials that may be included in a perovskite material device will be made in part with reference to FIG. 29. FIG. 29 is a stylized diagram of a tandem two-terminal perovskite material device 3900 according to some embodiments. Although various components of the device in FIG. 29 and other figures of the present disclosure depicting perovskite devices (e.g., FIGS. 1-2, 4-9, 31, and 32-33) are illustrated as discrete layers comprising contiguous material, it should be understood that such figures are stylized diagrams; thus, embodiments in accordance with it may include such discrete layers, and/or substantially intermixed, non-contiguous layers, consistent with the usage of “layers” previously discussed herein. The device 3900 includes first and second substrates 3901 and 3913. A first electrode 3902 is disposed upon an inner surface of the first substrate 3901, and a second electrode 3912 is disposed on an inner surface of the second substrate 3913. An active layer 3950 is sandwiched between the two electrodes 3902 and 3912. The active layer 3950 includes a mesoporous layer 3904; first and second photoactive materials 3906 and 3908; a charge transport layer (CTL) 3910, and several interfacial layers. FIG. 29 furthermore illustrates an example device 3900 according to embodiments wherein sub-layers of the active layer 3950 are separated by the interfacial layers, and further wherein interfacial layers are disposed upon each electrode 3902 and 3912. In particular, second, third, and fourth interfacial layers 3905, 3907, and 3909 are respectively disposed between each of the mesoporous layer 3904, first photoactive material 3906, second photoactive material 3908, and charge transport layer 3910. First and fifth interfacial layers 3903 and 3911 are respectively disposed between (i) the first electrode 3902 and mesoporous layer 3904; and (ii) the charge transport layer 3910 and second electrode 3912. Thus, the architecture of the example device depicted in FIG. 29 may be characterized as: substrate-electrode-active layer-electrode-substrate. The architecture of the active layer 3950 may be characterized as: interfacial layer-mesoporous layer-interfacial layer-photoactive material-interfacial layer-photoactive material-interfacial layer-charge transport layer-interfacial layer. In some embodiments, interfacial layers need not be present; or one or more interfacial layers may be included only between certain, but not all, components of an active layer and/or components of a device.

A substrate, such as either or both of first and second substrates 3901 and 3913, may be flexible or rigid. If two substrates are included, at least one should be transparent or translucent to electromagnetic (EM) radiation (such as, e.g., UV, visible, or IR radiation). If one substrate is included, it may be similarly transparent or translucent, although it need not be, so long as a portion of the device permits EM radiation to contact the active layer 3950. Suitable substrate materials include any one or more of: glass; sapphire; magnesium oxide (MgO); mica; polymers (e.g., PEN, PET, PEG, polyolefin, polypropylene, polyethylene, polycarbonate, PMMA, polyamide, vinyl, Kapton); ceramics; carbon; composites (e.g., fiberglass, Kevlar; carbon fiber); fabrics (e.g., cotton, nylon, silk, wool); wood; drywall; tiles (e.g. ceramic, composite, or clay); metal; steel; silver; gold; aluminum; magnesium; concrete; and combinations thereof.

As previously noted, an electrode (e.g., one of electrodes 3902 and 3912 of FIG. 29) may be either an anode or a cathode. In some embodiments, one electrode may function as a cathode, and the other may function as an anode. Either or both electrodes 3902 and 3912 may be coupled to leads, cables, wires, or other means enabling charge transport to and/or from the device 3900. An electrode may constitute any conductive material, and at least one electrode should be transparent or translucent to EM radiation, and/or be arranged in a manner that allows EM radiation to contact at least a portion of the active layer 3950. Suitable electrode materials may include any one or more of: indium tin oxide or tin-doped indium oxide (ITO); fluorine-doped tin oxide (FTO); cadmium oxide (CdO); zinc indium tin oxide (ZITO); aluminum zinc oxide (AZO); aluminum (Al); gold (Au); silver (Ag); calcium (Ca); chromium (Cr); copper (Cu); magnesium (Mg); titanium (Ti); steel; carbon (and allotropes thereof); doped carbon (e.g., nitrogen-doped); nanoparticles in core-shell configurations (e.g., silicon-carbon core-shell structure); and combinations thereof.

Mesoporous material (e.g., the material included in mesoporous layer 3904 of FIG. 29) may include any pore-containing material. In some embodiments, the pores may have diameters ranging from about 1 to about 100 nm; in other embodiments, pore diameter may range from about 2 to about 50 nm. Suitable mesoporous material includes any one or more of: any interfacial material and/or mesoporous material discussed elsewhere herein; aluminum (Al); bismuth (Bi); cerium (Ce); hafnium (Hf); indium (In); molybdenum (Mo); niobium (Nb); nickel (Ni); silicon (Si); titanium (Ti); vanadium (V); zinc (Zn); zirconium (Zr); an oxide of any one or more of the foregoing metals (e.g., alumina, ceria, titania, zinc oxide, zirconia, etc.); a sulfide of any one or more of the foregoing metals; a nitride of any one or more of the foregoing metals; and combinations thereof. In some embodiments, any material disclosed herein as an IFL may be a mesoporous material. In other embodiments, the device illustrated by FIG. 29 may not include a mesoporous material layer and include only thin-film, or “compact,” IFLs that are not mesoporous.

Photoactive material (e.g., first or second photoactive material 3906 or 3908 of FIG. 29) may comprise any photoactive compound, such as any one or more of silicon (for example, polycrystalline silicon, single-crystalline silicon, or amorphous silicon), cadmium telluride, cadmium sulfide, cadmium selenide, copper indium gallium selenide, copper indium selenide, copper zinc tin sulfide, gallium arsenide, germanium, germanium indium phosphide, indium phosphide, one or more semiconducting polymers (e.g., polythiophenes (e.g., poly(3-hexylthiophene) and derivatives thereof, or P3HT); carbazole-based copolymers such as polyheptadecanylcarbazole dithienylbenzothiadiazole and derivatives thereof (e.g., PCDTBT); other copolymers such as polycyclopentadithiophene-benzothiadiazole and derivatives thereof (e.g., PCPDTBT), polybenzodithiophenyl-thienothiophenediyl and derivatives thereof (e.g., PTB6, PTB7, PTB7-th, PCE-10); poly(triaryl amine) compounds and derivatives thereof (e.g., PTAA); polyphenylene vinylenes and derivatives thereof (e.g., MDMO-PPV, MEH-PPV), and combinations thereof.

In certain embodiments, photoactive material may instead or in addition comprise a dye (e.g., N719, N3, other ruthenium-based dyes). In some embodiments, a dye (of whatever composition) may be coated onto another layer (e.g., a mesoporous layer and/or an interfacial layer). In some embodiments, photoactive material may include one or more perovskite materials. Perovskite-material-containing photoactive substance may be of a solid form, or in some embodiments it may take the form of a dye that includes a suspension or solution comprising perovskite material. Such a solution or suspension may be coated onto other device components in a manner similar to other dyes. In some embodiments, solid perovskite-containing material may be deposited by any suitable means (e.g., vapor deposition, solution deposition, direct placement of solid material). Devices according to various embodiments may include one, two, three, or more photoactive compounds (e.g., one, two, three, or more perovskite materials, dyes, or combinations thereof). In certain embodiments including multiple dyes or other photoactive materials, each of the two or more dyes or other photoactive materials may be separated by one or more interfacial layers, or may be intermixed, at least in part.

In certain embodiments, the photoactive material may include any photoactive material described herein, such as, thin film semiconductors (e.g., CdTe, CZTS, CIGS), photoactive polymers, dye sensitized photoactive materials, fullerenes, small molecule photoactive materials, and crystalline and polycrystalline semiconductor materials (e.g., silicon, GaAs, InP, Ge). In yet other embodiments, one or both of active layers 3906a and 3908a may include a light emitting diode (LED), field effect transistor (FET), thin film battery layer, or combinations thereof. In embodiments, one of active layers 3906a and 3908a may include a photoactive material and the other may include a LED, FET, thin film battery layer, or combinations thereof.

As used herein, “charge transport material” refers to any material, solid, liquid, or otherwise, capable of collecting charge carriers (electrons or holes) and/or transporting charge carriers. Charge transport material (e.g., charge transport material of charge transport layer 3910 in FIG. 29) may include solid-state charge transport material (i.e., a colloquially labeled solid-state electrolyte), or it may include a liquid electrolyte and/or ionic liquid. In PV devices according to some embodiments, a charge transport material may be capable of transporting charge carriers to an electrode. Charge carriers may include holes (the transport of which could make the charge transport material just as properly labeled “hole transport material”) and electrons. Holes may be transported toward an anode, and electrons toward a cathode, depending upon placement of the charge transport material in relation to either a cathode or anode in a PV or other device. Suitable examples of charge transport material according to some embodiments may include any one or more of: perovskite material; I-/I3-; Co complexes; polythiophenes (e.g., poly(3-hexylthiophene) and derivatives thereof, or P3HT); carbazole-based copolymers such as polyheptadecanylcarbazole dithienylbenzothiadiazole and derivatives thereof (e.g., PCDTBT); other copolymers such as polycyclopentadithiophene-benzothiadiazole and derivatives thereof (e.g., PCPDTBT), polybenzodithiophenyl-thienothiophenediyl and derivatives thereof (e.g., PTB6, PTB7, PTB7-th, PCE-10); poly(triaryl amine) compounds and derivatives thereof (e.g., PTAA); Spiro-OMeTAD; polyphenylene vinylenes and derivatives thereof (e.g., MDMO-PPV, MEH-PPV); fullerenes and/or fullerene derivatives (e.g., C₆₀, PCBM); carbon nanotubes; graphite; graphene; carbon black; amorphous carbon; glassy carbon; carbon fiber; and combinations thereof. Charge transport material of some embodiments may be n- or p-type active, ambipolar, and/or intrinsic semi-conducting material. Charge transport material may be disposed proximate to one of the electrodes of a device. It may in some embodiments be disposed adjacent to an electrode, although in other embodiments an interfacial layer may be disposed between the charge transport material and an electrode (as shown, e.g., in FIG. 29 with the fifth interfacial layer 3911). In certain embodiments, the type of charge transport material may be selected based upon the electrode to which it is proximate. For example, if the charge transport material collects and/or transports holes, it may be proximate to an anode so as to transport holes to the anode. However, the charge transport material may instead be placed proximate to a cathode and be selected or constructed so as to transport electrons to the cathode.

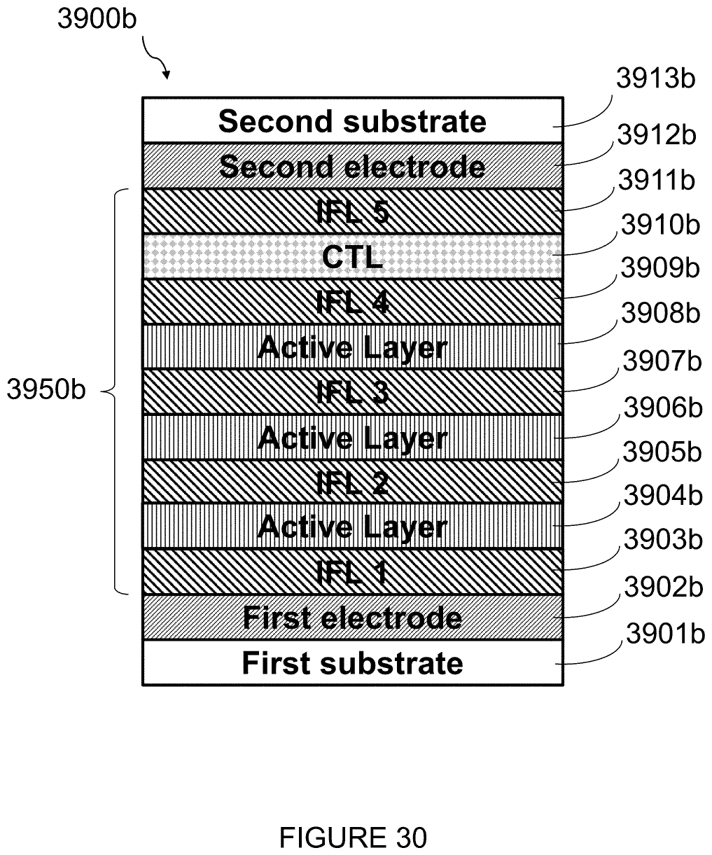

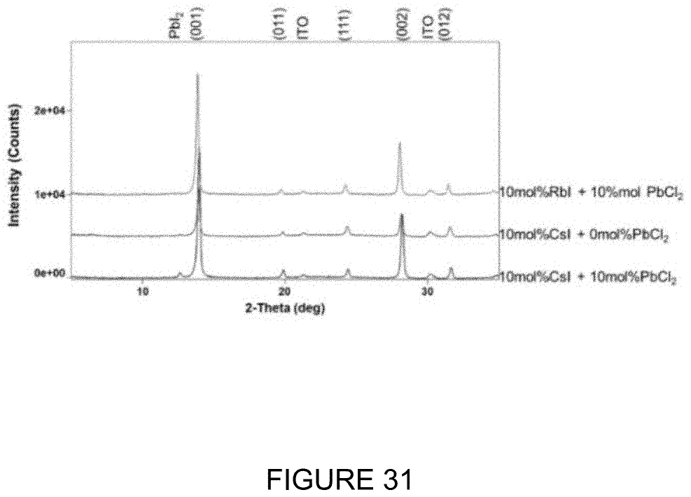

Additionally, in some embodiments, a perovskite material may have three or more active layers. As an example, FIG. 31 is a stylized diagram illustrating an embodiment of a two-terminal perovskite material device 3900b including three active layers and otherwise having a similar structure to perovskite material device 3900 illustrated by FIG. 29. FIG. 30 includes active layers 3904b, 3906b and 3908b. One or more of active layers 3904b, 3906b and 3908b may, in some embodiments, include any of the photoactive materials described above with respect to FIG. 29. Other layers illustrated of FIG. 30, such as layers 3901b, 3902b, 3903b, 3904b, 3905b (i.e., a recombination layer), 3907b (i.e., a recombination layer), 3909b, 3910b, 3911b, 3912b, and 3913b, may be analogous to such corresponding layers as described herein with respect to FIG. 29.

In some embodiments, a tandem PV device may be a four-terminal device, as shown in FIG. 32. The four-terminal device 2300 may include two sub-cells 2400 and 2500 which are electrically independent from the other. In some embodiments, the four-terminal device may include two sub-cells 2400 and 2500 that are mechanically stacked on top of each other but optically coupled, such that light that is transmitted through the front sub-cell 2400 reaches the back sub-cell 2500. The four-terminal PV 2300 includes a first substrate layer 2310, which may be glass (or a material similarly transparent to solar radiation) which allows solar radiation to transmit through the layer. The transparent layer of some embodiments may also be referred to as a superstrate or substrate, and it may comprise any one or more of a variety of rigid or flexible materials as discussed above.

The first PAM layer 2350 of the front sub-cell 2400 may be composed of electron donor or p-type material, and/or an electron acceptor or n-type material, and/or an ambipolar semiconductor, which exhibits both p- and n-type material characteristics, and/or an intrinsic semiconductor which exhibits neither n-type or p-type characteristics. Photoactive layer 2350 may, in some embodiments, include any photoactive materials described above with respect to FIGS. 29-30. The active layer or, as depicted in FIG. 32, the photoactive layer 2350, is sandwiched between two electrically conductive electrode layers 2320 and 2370. As previously noted, an active layer of some embodiments need not necessarily be photoactive, although in the device shown in FIG. 32, it is. In FIG. 32, the electrode layers may be a transparent conductor such as a fluorine-doped tin oxide (FTO material) or other material as described herein. In other embodiments second substrate 2390 and second electrode 2370 may be transparent. The electrode layer 2370 may be a transparent conductor such as an indium zinc oxide (IZO material) or other electrode material as described herein or is known in the art. The front sub-cell 2400 also includes interfacial layers (IFLs) 2330, 2340, 2350, 2355. The IFLs may include any suitable material described above. In certain embodiments, 2330 may be a nitride, 2340 may be NiO, 2355 may be fullerene, and/or 2360 may be SnO₂. Although shown with two IFLs on either side of the photoactive layer 2350, the front sub-cell 2400 may include zero, one, two, three, four, five, or more interfacial layers on either side of the photoactive material layer 2350. An IFL according to some embodiments may be semiconducting in character and may be either intrinsic, ambipolar, p-type, or n-type, or it may be dielectric in character. In some embodiments, the IFLs on the cathode side of the device (e.g., IFLs 2355 and 2360 as shown in FIG. 32) may be n-type, and the IFLs on the anode side of the device (e.g., IFL 2330 and 2340 as shown in FIG. 32) may be p-type. In other embodiments, however, the cathode-side IFLs may be p-type and the anode-side IFLs may be n-type. The front sub-cell 2400 may be attached to electrical leads by electrodes 2320 and 2370 and a discharge unit, such as a battery, motor, capacitor, electric grid, or any other electrical load.

The back sub-cell 2500 of the PV device 2300 may have a similar or different architecture to the front sub-cell 2400. The back sub-cell 2500 may include a second photoactive material, and in some embodiments, may include any photoactive material described above with respect to FIGS. 29-30. In one example, the back sub-cell 2500 may include electrodes, IFLs, and other layers in the same or a different architecture as the front sub-cell 2400. One or both of photoactive layers of the front sub-cell 2400 and back sub-cell 2500 may, in some embodiments, include any photoactive materials described above with respect to FIGS. 29-30, or one may include a photoactive material and the other may include a LED, FET, thin film battery layer, or combinations thereof. Layers such as substrates, electrodes, and IFLs of the front sub-cell 2400 and back sub-cell may be analogous to such corresponding layers as described herein with respect to FIGS. 29-30, and may include any materials or configurations described as suitable for those corresponding layers.

A non-conductive layer 2380 may be disposed between, and adjacent to, the front-sub-cell 2400 and back sub-cell 2500. As used herein, “non-conductive layer” means layers that are electrically non-conductive, and is not intended to define any thermal properties of the non-conductive layer, which may be thermally conductive or insulating. In some embodiments, the non-conductive layer 2380 may include, but is not limited to an adhesive, epoxy, glass, laminate, wax, polymer, resin, elastomer, thermoset, or any combination thereof. In some embodiments, the non-conductive layer 2380 may include poly vinyl acetate, polyolefins, polystyrenes, polyglycols, polyorganic acids, natural rubber, synthetic rubber, polyesters, nylons, polyamides, polyaryls, polynucleic acids, polysaccharides, polyurethanes, acrylonitrile butadiene styrene, acrylic, acrylic polymers, acrylic resins, cross-linked porous resins, and any combination or derivative thereof. Examples of polymers suitable for certain embodiments include, but are not limited to poly(ethylene-vinyl acetate) (EVA), high-density polyethylene (HDPE), low-density polyethylene (LDPE), polypropylene (PP), polystyrene (PS), polyethylene glycol (PEG/PEO), poly(methyl methacrylate) (PMMA), polyoxymethylene (POM), poly(acrylonitrile butadiene styrene) (ABS), polyphenylene sulfide (PPS), polytetrafluoroethylene (PTFE), polyvinylidene difluoride (PVDF), polyvinyl chloride (PVC), poly(ethylene terephthalate (PET), polylactic acid (PLA), polycarbonate (PC), polyether ether ketone (PEEK), polybutylene terephthalate (PBT), butylene rubber, polyisoprene, polyurethane (PU), polydimethylsiloxane (PDMS), urea formaldehyde resin, an epoxy resin, phenol formaldehyde resin (PF), derivatives thereof, and any combination thereof. The configuration of the polymer backbone of the binding polymers may be isotactic, syndiotactic, or atactic. In one example, the non-conductive layer 2380 is transparent. In another example, the non-conductive layer 2380 is not transparent.

Additional, more specific, example embodiments of perovskite devices will be discussed in terms of further stylized depictions of example devices. The stylized nature of these depictions, FIGS. 29-30 and 32, similarly is not intended to restrict the type of device which may in some embodiments be constructed in accordance with any one or more of FIGS. 29-30 and 32. That is, the architectures exhibited in FIGS. 29-30 and 32 may be adapted so as to provide the BHJs, batteries, FETs, hybrid PV batteries, serial multi-cell PVs, parallel multi-cell PVs and other similar devices of other embodiments of the present disclosure, in accordance with any suitable means (including both those expressly discussed elsewhere herein, and other suitable means, which will be apparent to those skilled in the art with the benefit of this disclosure).

Formation of the Perovskite Material Active Layer

In certain embodiments, the perovskite material may be deposited as an active layer in a PV device by, for example, blade coating, drop casting, spin casting, slot-die printing, screen printing, or ink-jet printing onto a substrate layer using the steps described below.

First, a lead halide precursor ink is formed. An amount of lead halide may be massed in a clean, dry vessel in a controlled atmosphere environment (e.g., a controlled atmosphere box with glove-containing portholes allows for materials manipulation in an air-free environment). Suitable lead halides include, but are not limited to, lead (II) iodide, lead (II) bromide, lead (II) chloride, and lead (II) fluoride. The lead halide may comprise a single species of lead halide or it may comprise a lead halide mixture in a precise ratio. In certain embodiments, the lead halide mixture may comprise any binary, ternary, or quaternary ratio of 0.001-100 mol % of iodide, bromide, chloride, or fluoride. In one embodiment, the lead halide mixture may comprise lead (II) chloride and lead (II) iodide in a ratio of about 10:90 mol:mol. In other embodiments, the lead halide mixture may comprise lead (II) chloride and lead (II) iodide in a ratio of about 5:95, about 7.5:92.5, or about 15:85 mol:mol.

Alternatively, other lead salt precursors may be used in conjunction with or in lieu of lead halide salts to form the precursor ink. Suitable precursor salts may comprise any combination of lead (II) or lead (IV) and the following anions: nitrate, nitrite, carboxylate, acetate, acetonyl acetonate, formate, oxalate, sulfate, sulfite, thiosulfate, phosphate, tetrafluoroborate, hexafluorophosphate, tetra(perfluorophenyl) borate, hydride, oxide, peroxide, hydroxide, nitride, arsenate, arsenite, perchlorate, carbonate, bicarbonate, chromate, dichromate, iodate, bromate, chlorate, chlorite, hypochlorite, hypobromite, cyanide, cyanate, isocyanate, fulminate, thiocyanate, isothiocyanate, azide, tetracarbonylcobaltate, carbamoyldicyanomethanide, dicyanonitrosomethanide, dicyanamide, tricyanomethanide, amide, and permanganate.

The precursor ink may further comprise a lead (II) or lead (IV) salt in mole ratios of 0 to 100% to the following metal ions Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr as a salt of the aforementioned anions.

A solvent may then be added to the vessel to dissolve the lead solids to form the lead halide precursor ink. Suitable solvents include, but are not limited to, dry N-cyclohexyl-2-pyrrolidone, alkyl-2-pyrrolidone, dimethylformamide, dialkylformamide, dimethylsulfoxide (DMSO), methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, alkylnitrile, arylnitrile, acetonitrile, alkoxylalcohols, alkoxyethanol, 2-methoxyethanol, glycols, propylene glycol, ethylene glycol, and combinations thereof. In one embodiment, the lead solids are dissolved in dry dimethylformamide (DMF). In some embodiments, the solvent may further comprise 2-methoxyethanol and acetonitrile. In some embodiments, 2-methoxyethanol and acetonitrile may be added in a volume ratio of from about 25:75 to about 75:25, or at least 25:75. In certain embodiments, the solvent may include a ratio of 2-methoxyethanol and acetonitrile to DMF of from about 1:100 to about 1:1, or from about 1:100 to about 1:5, on a volume basis. In certain embodiments, the solvent may include a ratio of 2-methoxyethanol and acetonitrile to DMF of at least about 1:100 on a volume basis.

In certain embodiments, the lead solids may be dissolved at a temperature between about 20° C. to about 150° C. In one embodiment, the lead halide solids are dissolved at about 85° C. The lead solids may be dissolved for as long as necessary to form a solution, which may take place over a time period up to about 72 hours. The resulting solution forms the base of the lead halide precursor ink. In some embodiments, the lead halide precursor ink may have a lead halide concentration between about 0.001M and about 10M, or about 1 M.

Optionally, certain additives may be added to the lead halide precursor ink to affect the final perovskite crystallinity and stability. In some embodiments, the lead halide precursor ink may further comprise an amino acid (e.g., 5-aminovaleric acid, histidine, glycine, lysine), an amino acid hydrohalide (e.g., 5-amino valeric acid hydrochloride), an IFL surface-modifying (SAM) agent (such as those discussed earlier in the specification), or a combination thereof. Amino acids suitable for lead halide precursor inks may include, but are not limited to α-amino acids, β-amino acids, γ-amino acids, δ-amino acids, and any combination thereof. In one embodiment, formamidinium chloride may be added to the lead halide precursor ink. In other embodiments, the halide of any cation discussed earlier in the specification may be used. In some embodiments, combinations of additives may be added to the lead halide precursor ink including, for example, the combination of formamidinium chloride and 5-amino valeric acid hydrochloride.

The additives, including, in some embodiments, formamidinium chloride and/or 5-amino valeric acid hydrochloride, may be added to the lead halide precursor ink at various concentrations depending on the desired characteristics of the resulting perovskite material. In one embodiment, the additives may be added in a concentration of about 1 nM to about 1 M, from about 1 μM to about 1 M, or from about 1 μM to about 1 mM.

Optionally, in certain embodiments, water may be added to the lead halide precursor ink. By way of explanation, and without limiting the disclosure to any particular theory or mechanism, the presence of water affects perovskite thin-film crystalline growth. Under normal circumstances, water may be absorbed as vapor from the air. However, it is possible to control the perovskite PV crystallinity through the direct addition of water to the lead halide precursor ink in specific concentrations. Suitable water includes distilled, deionized water, or any other source of water that is substantially free of contaminants (including minerals). It has been found, based on light I-V sweeps, that the perovskite PV light-to-power conversion efficiency may nearly triple with the addition of water compared to a completely dry device.

The water may be added to the lead halide precursor ink at various concentrations depending on the desired characteristics of the resulting perovskite material. In one embodiment, the water may be added in a concentration of about 1 nL/mL to about 1 mL/mL, from about 1 μL/mL to about 0.1 mL/mL, or from about 1 μL/mL to about 20 μL/mL.

The lead halide precursor ink may then be deposited on the desired substrate. Suitable substrate layers may include any of the substrate layers identified earlier in this disclosure. As noted above, the lead halide precursor ink may be deposited through a variety of means, including but not limited to, drop casting, spin coating (spin casting), slot-die printing, ink-jet printing, gravure printing, screen printing, sputtering, PE-CVD, atomic-layer deposition, thermal evaporation, spray coating, and any combination thereof. In certain embodiments, the lead halide precursor ink may be spin-coated onto the substrate at a speed of about 500 rpm to about 10,000 rpm for a time period of about 5 seconds to about 600 seconds. In one embodiment, the lead halide precursor ink may be spin-coated onto the substrate at about 3000 rpm for about 30 seconds. The lead halide precursor ink may be deposited on the substrate at an ambient atmosphere in a humidity range of about 0% relative humidity to about 50% relative humidity. The lead halide precursor ink may then be allowed to dry in a substantially water-free atmosphere, i.e., less than 30% relative humidity, to form a thin film.

The thin film may then be thermally annealed for a time period up to about 24 hours at a temperature of about 20° C. to about 300° C. In one embodiment, the thin film may be thermally annealed for about ten minutes at a temperature of about 50° C. The perovskite material active layer may then be completed by a conversion process in which the precursor film is submerged or rinsed with a solution comprising a solvent or mixture of solvents (e.g., DMF, isopropanol, methanol, ethanol, butanol, chloroform chlorobenzene, dimethylsulfoxide, water) and salt (e.g., methylammonium iodide, formamidinium iodide, guanidinium iodide, 1,2,2-triaminovinylammonium iodide, 5-aminovaleric acid hydroiodide) in a concentration between 0.001M and 10M. In certain embodiments, the thin films may also be thermally post-annealed in the same fashion as in the first line of this paragraph.

In some embodiments, a lead salt precursor may be deposited onto a substrate to form a lead salt thin film. The substrate may have a temperature about equal to ambient temperature or have a controlled temperature between 0° C. and 500° C. The lead salt precursor may be deposited by any of the methods discussed above with respect to the lead halide precursor ink. In certain embodiments, the deposition of the lead salt precursor may comprise sheet-to-sheet or roll-to-roll manufacturing methodologies. Deposition of the lead salt precursor may be performed in a variety of atmospheres at ambient pressure or at pressures less than atmospheric or ambient (e.g., 1 mTorr to 500 mTorr). The deposition atmosphere may comprise ambient air, a controlled humidity environment (e.g., 0-100 g H₂O/m³ of gas), pure argon, pure nitrogen, pure oxygen, pure hydrogen, pure helium, pure neon, pure krypton, pure CO₂ or any combination of the preceding gases. A controlled humidity environment may include an environment in which the absolute humidity or the % relative humidity is held at a fixed value, or in which the absolute humidity or the % relative humidity varies according to predetermined set points or a predetermined function. In particular embodiments, deposition may occur in a controlled humidity environment having a % relative humidity greater than or equal to 0% and less than or equal to 50%. In other embodiments, deposition may occur in a controlled humidity environment containing greater than or equal to 0 g H₂O/m³ gas and less than or equal to 20 g H₂O/m³ gas. Unless described as otherwise, any annealing or deposition step described herein may be carried out under the preceding conditions.

The lead salt precursor may be a liquid, a gas, solid, or combination of these states of matter such as a solution, suspension, colloid, foam, gel, or aerosol. In some embodiments, the lead salt precursor may be a solution containing one or more solvents. For example, the lead salt precursor may contain one or more of N-cyclohexyl-2-pyrrolidone, alkyl-2-pyrrolidone, dimethylformamide, dialkylformamide, dimethylsulfoxide (DMSO), acetonitrile, methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, and combinations thereof. The lead salt precursor may comprise a single lead salt (e.g., lead (II) iodide, lead (II) thiocyanate) or any combination of those disclosed herein (e.g., PbI₂+PbCl₂; PbI₂+Pb(SCN)₂). The lead salt precursor may also contain one or more additives such as an amino acid (e.g., 5-aminovaleric acid hydroiodide), 1,8-diiodooctane, 1,8-dithiooctane, formamidinium halide, acetic acid, trifluoroacetic acid, a methylammonium halide, or water. The lead salt precursor may be allowed to dry in a substantially water-free atmosphere, i.e., less than 30% relative humidity, to form a thin film. The lead salt thin film may then be thermally annealed for the same amount of times and under the same conditions as discussed above with respect to the lead halide precursor ink thin film. The annealing environment may have the same pressures and atmosphere as the lead salt deposition environments and conditions discussed above. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas

After the lead salt precursor is deposited, a second salt precursor (e.g., formamidinium iodide, formamidinium thiocyanate, guanidinium thiocyanate) may be deposited onto the lead salt thin film, where the lead salt thin film may have a temperature about equal to ambient temperature or have a controlled temperature between 0° C. and 500° C. The second salt precursor, in some embodiments, may be deposited at ambient temperature or at elevated temperature between about 25° C. and 125° C. The second salt precursor may be deposited any of the methods discussed above with respect to the lead halide precursor ink. Deposition of the second salt precursor may be in the same environments and under the same conditions as discussed above with respect to the first salt precursor.

In some embodiments, the second salt precursor may be a solution containing one or more of the solvents (e.g., one or more of the solvents discussed above with respect to the first lead salt precursor).

After deposition of the lead salt precursor and second salt precursor, the substrate may be annealed. Annealing the substrate may convert the lead salt precursor and second salt precursor to a perovskite material, (e.g. FAPbI₃, GAPb(SCN)₃, FASnI₃). The annealing may occur in the same environment and under the same conditions as the lead salt deposition environments and conditions discussed above. In particular embodiments, annealing may occur in a controlled humidity environment having a % relative humidity greater than or equal to 0% and less than or equal to 50%. In other embodiments, annealing may occur in a controlled humidity environment containing greater than or equal to 0 g H₂O/m³ gas and less than or equal to 20 g H₂O/m³ gas. In some embodiments, annealing may occur at a temperature greater than or equal to 50° C. and less than or equal to 300° C.

For example, in a particular embodiment, a FAPbI₃ perovskite material may be formed by the following process. First, a lead (II) halide precursor comprising about a 90:10 mole ratio of PbI₂ to PbCl₂ dissolved in anhydrous DMF may be deposited onto a substrate by spin-coating or slot-die printing. The lead halide precursor ink may be allowed to dry in a substantially water-free atmosphere, i.e., less than 30% relative humidity, for approximately one hour (+15 minutes) to form a thin film. The thin film may be subsequently thermally annealed for about ten minutes at a temperature of about 50° C. (±10° C.). Next, a formamidinium iodide precursor comprising a 25-60 mg/mL concentration of formamidinium iodide dissolved in anhydrous isopropyl alcohol may be deposited onto the lead halide thin film by spin coating or slot-die printing. After depositing the lead halide precursor and formamidinium iodide precursor, the substrate may be annealed at about 25% relative humidity (about 4 to 7 g H₂O/m³ air) and between about 125° C. and 200° C. to form a formamidinium lead iodide (FAPbI₃) perovskite material.

In another embodiment, a perovskite material may comprise C′CPbX₃, where C′ is one or more Group 1 metals (e.g., Li, Na, K, Rb, Cs). In a particular embodiment M′ may be cesium (Cs). In yet other embodiments, a perovskite material may comprise C′ᵥC_{w}Pb_{y}X_{z}, where C′ is one or more Group 1 metals and v, w, y, and z represent real numbers between 1 and 20. In certain embodiments, the perovskite material may be deposited as an active layer in a PV device by, for example, drop casting, spin casting, gravure coating, blade coating, reverse gravure coating, slot-die printing, screen printing, or ink-jet printing onto a substrate layer.

First, a lead halide solution is formed. The lead halide solution may be prepared in any of the same methods and with similar compositions as the lead halide precursor ink discussed above. Other lead salt precursors (e.g., those discussed above with respect to lead halide precursor inks) may be used in conjunction with or in lieu of lead halide salts to form a lead salt solution.

Next, a Group 1 metal halide solution is formed. An amount of Group 1 metal halide may be massed in a clean, dry vessel in a controlled atmosphere environment. Suitable Group 1 metal halides include, but are not limited to, cesium iodide, cesium bromide, cesium chloride, cesium fluoride, rubidium iodide, rubidium bromide, rubidium chloride, rubidium fluoride, lithium iodide, lithium bromide, lithium chloride, lithium fluoride, sodium iodide, sodium bromide, sodium chloride, sodium fluoride, potassium iodide, potassium bromide, potassium chloride, potassium fluoride. The Group 1 metal halide may comprise a single species of Group 1 metal halide or it may comprise a Group 1 metal halide mixture in a precise ratio.

Alternatively, other Group 1 metal salt precursors may be used in conjunction with or in lieu of Group 1 metal halide salts to form a Group 1 metal salt solution. Suitable precursor Group 1 metal salts may comprise any combination of Group 1 metals and the following anions: nitrate, nitrite, carboxylate, acetate, formate, oxalate, sulfate, sulfite, thiosulfate, phosphate, tetrafluoroborate, hexafluorophosphate, tetra(perfluorophenyl) borate, hydride, oxide, peroxide, hydroxide, nitride, arsenate, arsenite, perchlorate, carbonate, bicarbonate, chromate, dichromate, iodate, bromate, chlorate, chlorite, hypochlorite, hypobromite, cyanide, cyanate, isocyanate, fulminate, thiocyanate, isothiocyanate, azide, tetracarbonylcobaltate, carbamoyldicyanomethanide, dicyanonitrosomethanide, dicyanamide, tricyanomethanide, amide, and permanganate.

A solvent may then be added to the vessel to dissolve the Group 1 metal halide solids to form the Group 1 metal halide solution. Suitable solvents include, but are not limited to, dry N-cyclohexyl-2-pyrrolidone, alkyl-2-pyrrolidone, dimethylformamide (DMF), dialkylformamide, dimethylsulfoxide (DMSO), acetonitrile, methanol, ethanol, propanol, butanol, tetrahydrofuran, formamide, tert-butylpyridine, pyridine, alkylpyridine, pyrrolidine, chlorobenzene, dichlorobenzene, dichloromethane, chloroform, and combinations thereof. In one embodiment, the lead solids are dissolved in dry dimethylsulfoxide (DMSO). The Group 1 metal halide solids may be dissolved at a temperature between about 20° C. to about 150° C. In one embodiment, the Group 1 metal halide solids are dissolved at room temperature (i.e., about 25° C.). The Group 1 metal halide solids may be dissolved for as long as necessary to form a solution, which may take place over a time period up to about 72 hours. The resulting solution forms the Group 1 metal halide solution. In some embodiments, the Group 1 metal halide solution may have a Group 1 metal halide concentration between about 0.001M and about 10M, or about 1 M. In some embodiments, the Group 1 metal halide solution may further comprise an amino acid (e.g., 5-aminovaleric acid, histidine, glycine, lysine), an amino acid hydrohalide (e.g., 5-amino valeric acid hydrochloride), an IFL surface-modifying (SAM) agent (such as those discussed earlier in the specification), or a combination thereof.

Next, the lead halide solution and the Group 1 metal halide solution are mixed to form a thin-film precursor ink. The lead halide solution and Group 1 metal halide solution may be mixed in a ratio such that the resulting thin-film precursor ink has a molar concentration of the Group 1 metal halide that is between 0% and 25% of the molar concentration of the lead halide. In particular embodiments, the thin-film precursor ink may have a molar concentration of the Group 1 metal halide that is 1%, 5%, 10%, 15%, 20%, or 25% of the molar concentration of the lead halide. In some embodiments the lead halide solution and the Group 1 metal halide solution may be stirred or agitated during or after mixing.

The thin-film precursor ink may then be deposited on the desired substrate through any of the deposition means discussed above. Suitable substrate layers may include any of the substrate layers identified earlier in this disclosure. In certain embodiments, the thin-film precursor ink may be spin-coated onto the substrate at a speed of about 500 rpm to about 10,000 rpm for a time period of about 5 seconds to about 600 seconds. In one embodiment, the thin-film precursor ink may be spin-coated onto the substrate at about 3000 rpm for about 30 seconds. The thin-film precursor ink may be deposited on the substrate at an ambient atmosphere in a humidity range of about 0% relative humidity to about 50% relative humidity. The thin-film precursor ink may then be allowed to dry in a substantially water-free atmosphere, i.e., less than 30% relative humidity or 7 g H₂O/m3, to form a thin film.

The thin film can then be thermally annealed for a time period up to about 24 hours at a temperature of about 20° C. to about 300° C. In one embodiment, the thin film may be thermally annealed for about ten minutes at a temperature of about 50° C. The perovskite material active layer may then be completed by a conversion process in which the precursor film is submerged or rinsed with a salt solution comprising a solvent or mixture of solvents (e.g., DMF, isopropanol, methanol, ethanol, butanol, chloroform chlorobenzene, dimethylsulfoxide, water) and salt (e.g., methylammonium iodide, formamidinium iodide, guanidinium iodide, 1,2,2-triaminovinylammonium iodide, 5-aminovaleric acid hydroiodide) in a concentration between 0.001M and 10M. In certain embodiments, the perovskite material thin films can also be thermally post-annealed in the same fashion as in the first line of this paragraph.

In some embodiments, the salt solution may be prepared by massing the salt in a clean, dry vessel in a controlled atmosphere environment. Suitable salts include, but are not limited to, methylammonium iodide, formamidinium iodide, guanidinium iodide, imidazolium iodide, ethene tetramine iodide, 1,2,2-triaminovinylammonium iodide, and 5-aminovaleric acid hydroiodide. Other suitable salts may include any organic cation described above in the section entitled “Perovskite Material.” The salt may comprise a single species of salt or it may comprise a salt mixture in a precise ratio. Next, a solvent may then be added to the vessel to dissolve the salt solids to form the salt solution. Suitable solvents include those listed in the preceding paragraph, and combinations thereof. In one embodiment, formamidinium iodide salt solids are dissolved in isopropanol. The salt solids may be dissolved at a temperature between about 20° C. to about 150° C. In one embodiment, the salt solids are dissolved at room temperature (i.e. about 25° C.). The salt solids may be dissolved for as long as necessary to form a solution, which may take place over a time period up to about 72 hours. The resulting solution forms the salt solution. In some embodiments, the salt solution may have a salt concentration between about 0.001M and about 10M. In one embodiment, the salt solution has a salt concentration of about 1 M.

For example, using the process described above with a lead (II) iodide solution, a cesium iodide solution, and a methylammonium (MA) iodide salt solution may result in a perovskite material having the a formula of CsᵢMA₁₋ᵢPbI₃, where i equals a number between 0 and 1. As another example, using a lead (II) iodide solution, a rubidium iodide solution, and a formamidinium (FA) iodide salt solution may result in a perovskite material having the a formula of RbᵢFA₁₋ᵢPbI₃, where i equals a number between 0 and 1. As another example, using a lead (II) iodide solution, a cesium iodide solution, and a formamidinium (FA) iodide salt solution may result in a perovskite material having the a formula of CsᵢFA₁₋ᵢPbI₃, where i equals a number between 0 and 1. As another example, using a lead (II) iodide solution, a potassium iodide solution, and a formamidinium (FA) iodide salt solution may result in a perovskite material having the a formula of KᵢFA₁₋ᵢPbI₃, where i equals a number between 0 and 1. As another example, the using a lead (II) iodide solution, a sodium iodide solution, and a formamidinium (FA) iodide salt solution may result in a perovskite material having the a formula of NᵢFA₁₋ᵢPbI₃, where i equals a number between 0 and 1. As another example, the using a lead (II) iodide-lead (II) chloride mixture solution, a cesium iodide solution, and a formamidinium (FA) iodide salt solution may result in a perovskite material having the a formula of CsᵢFA₁₋ᵢPbI_{3-y}Cl_{y}, where i equals a number between 0 and 1 and y represents a number between 0 and 3.

In a particular embodiment, the lead halide solution as described above may have a ratio of 90:10 of PbI₂ to PbCl₂ on a mole basis. A cesium iodide (CsI) solution may be added to the lead halide solution by the method described above to form a thin film precursor ink with 10 mol % CsI. A FAPbI₃ perovskite material may be produced according to the method described above using this thin film precursor solution. The addition of cesium ions through the CsI solution as described above may cause chloride anions and cesium atoms to incorporate into the FAPbI3 crystal lattice. This may result in a greater degree of lattice contraction compared to addition of cesium or rubidium ions as described above without addition of chloride ions. Table 1 below shows lattice parameters for FAPbI₃ perovskite materials with 10 mol % rubidium and 20 mol % chloride (e.g. 10 mol % PbCl2), 10 mol % cesium, and 10 mol % cesium with 20 mol % chloride, wherein the mol % concentration represents the concentration of the additive with respect to the lead atoms in the lead halide solution. As can be seen in Table 1, the FAPbI₃ perovskite material with cesium and chloride added has smaller lattice parameters than the other two perovskite material samples.

TABLE 1

| | (001) | (002) |
|---|---|---|
| Sample Details | d-spacing | d-spacing |
| 10 mol % RbI + | 6.3759(15) | 3.1822(5) |
| 10 mol % PbCl₂ | | |
| 10 mol % CsI + | 6.3425(13) | 3.1736(8) |
| 0 mol % PbCl₂ | | |
| 10 mol % CsI + | 6.3272(13) | 3.1633(4) |
| 10 mol % PbCl₂ | | |

Additionally, data shows that the FAPbI₃ perovskite material with rubidium, cesium and/or chloride added has a Pm3−m cubic structure. FAPbI₃ perovskites with up to and including 10 mol % Rb and 10 mol % Cl, or 10 mol % Cs, or 10 mol % Cs and 10 mol % Cl have been observed to maintain a cubic Pm3−m cubic crystal structure. FIG. 31 shows x-ray diffraction patterns corresponding to each of the samples presented in Table 1. Tables 2-4 provide the x-ray diffraction peaks and intensity for the three perovskite materials shown in Table 1. The data were collected at ambient conditions on a Rigaku Miniflex 600 using a Cu Kα radiation source at a scan rate of 1.5 degrees 2θ/min.

TABLE 2
10 mol % RbI + 10 mol % PbCl2

| 2-theta | d | Height | Peak Identity |
|---|---|---|---|
| (deg) | (ang.) | (cps) | (phase, miller index) |
| | | | PbI2, (001) |
| 13.878(3) | 6.3759(15) | 12605(126) | Perovskite, (001) |
| 19.707(15) | 4.501(3) | 489(25) | Perovskite, (011) |
| 21.320(14) | 4.164(3) | 286(19) | ITO, (112) |
| 24.227(19) | 3.671(3) | 1022(36) | Perovskite, (111) |
| 28.017(4) | 3.1822(5) | 5683(84) | Perovskite, (002) |
| 30.13(4) | 2.964(4) | 344(21) | ITO, (112) |
| 31.403(14) | 2.8464(13) | 913(34) | Perovskite, (012) |

TABLE 3
10 mol % CsI & 0 mol % PbCl2

| 2-theta | d | Height | Peak identity |
|---|---|---|---|
| (deg) | (ang.) | (cps) | phase (miller index) |
| 12.614(14) | 7.012(8) | 99(11) | PbI2, (001) |
| 13.952(3) | 6.3425(13) | 4921(78) | Perovskite,(001) |
| 19.826(12) | 4.475(3) | 392(22) | Perovskite, (011) |
| 21.274(14) | 4.173(3) | 281(19) | ITO, (112) |
| 24.333(15) | 3.655(2) | 1031(36) | Perovskite, (111) |
| 28.094(7) | 3.1736(8) | 2332(54) | Perovskite, (002) |
| 30.15(4) | 2.962(4) | 364(21) | ITO, (112) |
| 31.531(12) | 2.8351(10) | 941(34) | Perovskite, (012) |

TABLE 4
10 mol % CsI & 10 mol % PbCl2

| 2-theta | d | Height | Peak Identity |
|---|---|---|---|
| (deg) | (ang.) | (cps) | phase (miller index) |
| 12.635(6) | 7.000(3) | 395(22) | PbI2, (001) |
| 13.985(3) | 6.3272(13) | 13692(131) | Perovskite, (001) |
| 19.867(11) | 4.465(2) | 807(32) | Perovskite, (011) |
| 21.392(13) | 4.150(2) | 254(18) | ITO, (112) |
| 24.41(2) | 3.643(3) | 918(34) | Perovskite, (111) |
| 28.188(4) | 3.1633(4) | 6797(92) | Perovskite, (002) |
| 30.14(4) | 2.963(4) | 348(21) | ITO, (112) |
| 31.633(15) | 2.8262(13) | 1027(36) | Perovskite, (012) |

A geometrically expected x-ray diffraction pattern for cubic Pm3−m material with a lattice constant=6.3375 Å under Cu-Kα radiation is shown in Table 5. As can be seen from the data, the perovskite materials produced with 10 mol % Rb and 10 mol % Cl, 10 mol % Cs, and 10% Cs and 10% Cl each have diffraction patterns conforming to the expected pattern for a cubic, Pm3−m perovskite material.

TABLE 5
Geometrically Expected Diffraction Pattern for Cubic Pm3-m, lattice
constant = 6.3375 Å; Cu—Kα Radiation)

| | d-spacing | |
|---|---|---|
| 2-Theta (degrees) | (angstroms) | Miller Index |
| 13.963 | 6.3375 | (0 0 1) |
| 19.796 | 4.4813 | (0 1 1) |
| 24.306 | 3.659 | (1 1 1) |
| 28.138 | 3.1688 | (0 0 2) |
| 31.541 | 2.8342 | (0 1 2) |

Lead-Sequestration Material Layer

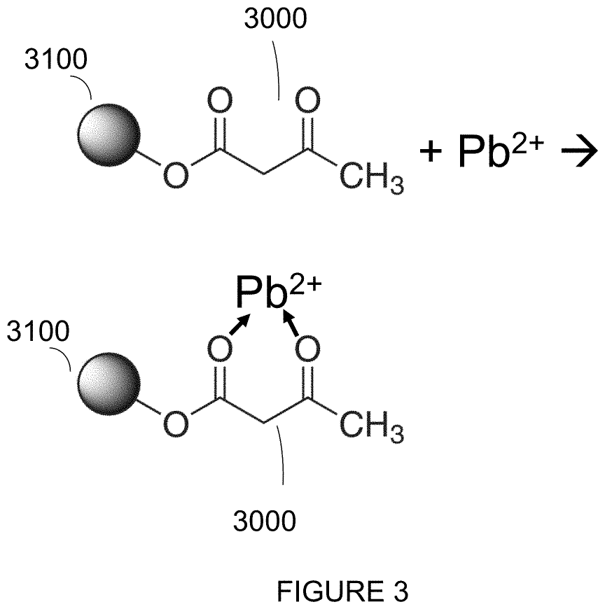

As used herein, “lead-sequestration material” refers to a material that comprises at least one lead-sequestration compound including one or more lead binding groups as a substituent (e.g., moiety or functional group) of the lead-sequestration compound. Examples of lead-binding groups suitable for certain embodiments of the present disclosures include, but are not limited to oxide, hydroxide, amine, amide, ammonium, carboxylate, carboxylic acid, aldehyde, ester, ether, phosphine, phosphinate, phosphonate, phosphate, sulfide, sulfate, and any combination thereof. FIG. 3 illustrates an example of lead sequestration mechanics. In the example depicted in FIG. 3, a lead-sequestration compound comprising an acetylacetonate lead binding group 3000 may be attached to a particle 3100. As shown in FIG. 3, a strong ionic or coordination-covalent interaction between Pb²⁺ and the acetylacetonate group 3000 may sequester lead ions. Other Pb orbital/p-orbital overlap, such as the Pb orbitals overlapping with a, for example, C—C and C—O pi-bond, may also sufficiently bind Pb such that it is considered sequestered. Among the many potential advantages to the methods, compositions and devices of the present disclosure, only some of which are alluded to herein, lead sequestration materials of the present disclosure may sequester free lead ions in perovskite devices and reduce leakage of lead ion or other metal ions.

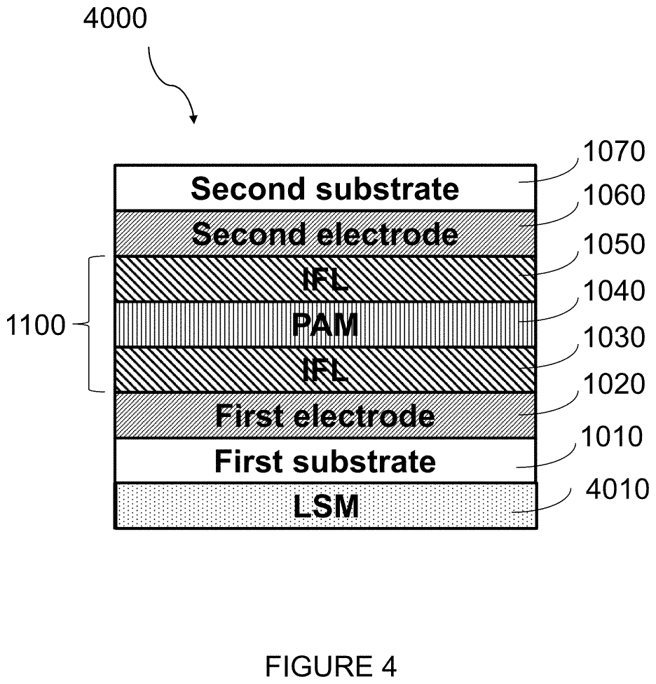

In certain embodiments, a perovskite material device may include a lead-sequestration material, either as a separate lead-sequestration layer or as a part of one or more other device layers. FIG. 4 is a stylized diagram of a perovskite material device 4000 according to some embodiments of the present disclosure. As an example, FIG. 4 illustrates an embodiment of a perovskite material device 4000 having a lead-sequestration material (LSM) layer 4010. The perovskite material device 4000 has a similar structure to the perovskite material device 1000 illustrated in FIG. 1.

In one embodiment, a lead-sequestration material layer is deposited or applied on the front of a perovskite material device. For example, in FIG. 4, the lead-sequestration material layer 4010 is deposited or applied on the surface of the first substrate 1010. In this example, the lead-sequestration material layer 4010 may be transparent. In one embodiment, a lead-sequestration material may be in the form of solid composites or solution ink that can be processed into thin films or coatings by heat extrusion, blade coating, slot-die coating, spin coating, nozzle spraying, and/or dip-casting. In another embodiment, the lead-sequestration material layer is insoluble in water. In some embodiments, the lead-sequestration material layer 4010 may be a coating, deposit, film, thin-film, or the like.

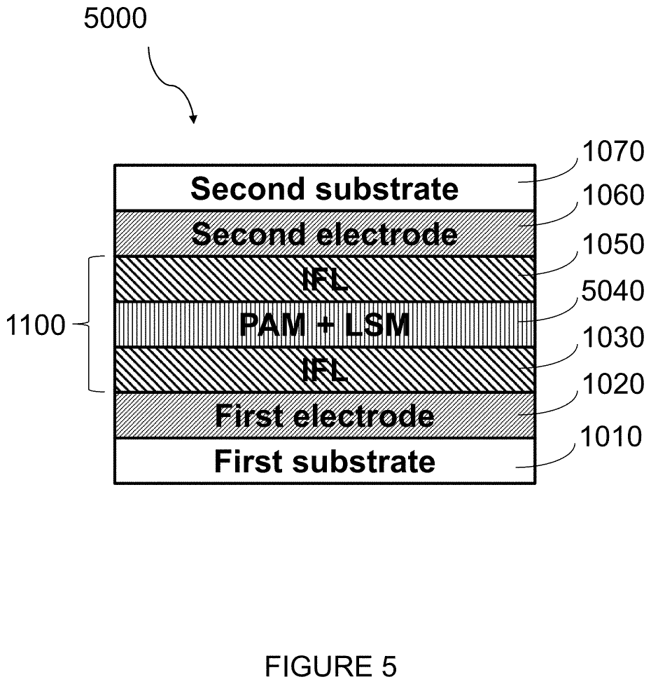

In one embodiment, a photoactive material layer may include a lead-sequestration material. FIG. 5 is a stylized diagram of a perovskite material device 5000 according to some embodiments. As an example, FIG. 5 illustrates an embodiment of a perovskite material device 5000 having a PAM layer that includes a lead-sequestration material (LSM) 5040. The perovskite material device 5000 has a similar structure to the perovskite material device 1000 illustrated in FIG. 1. In one embodiment, the lead-sequestration material is mixed with the perovskite precursors (e.g., added to a precursor ink) prior to forming the perovskite material layer. In certain embodiments, the volume ratio of the perovskite to the lead-sequestration material in the perovskite material layer is from about 0.01 to about 50. A person skilled in the art, with the benefit of this disclosure, would understand how to determine the appropriate volume ratio for a given perovskite material device. In another embodiment, the layer 5040 comprising the lead-sequestration material may be a composite material of a PAM and one or more lead-sequestration materials.

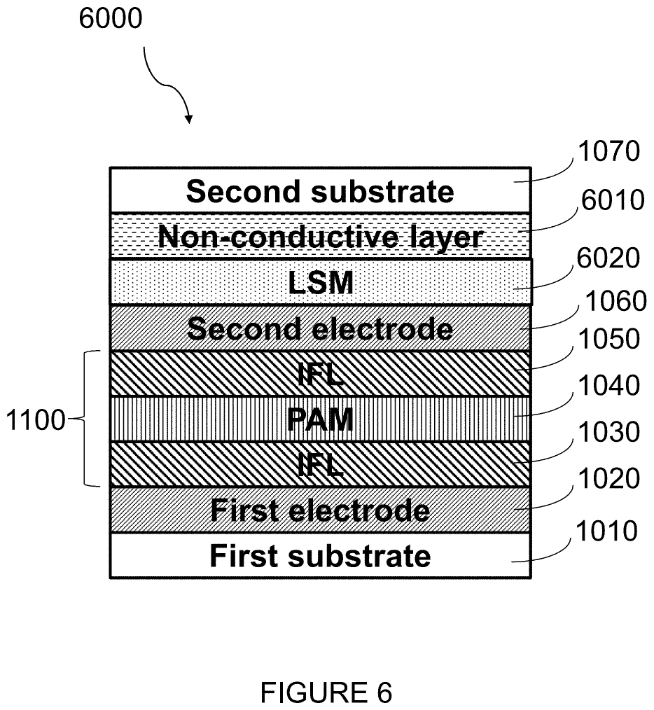

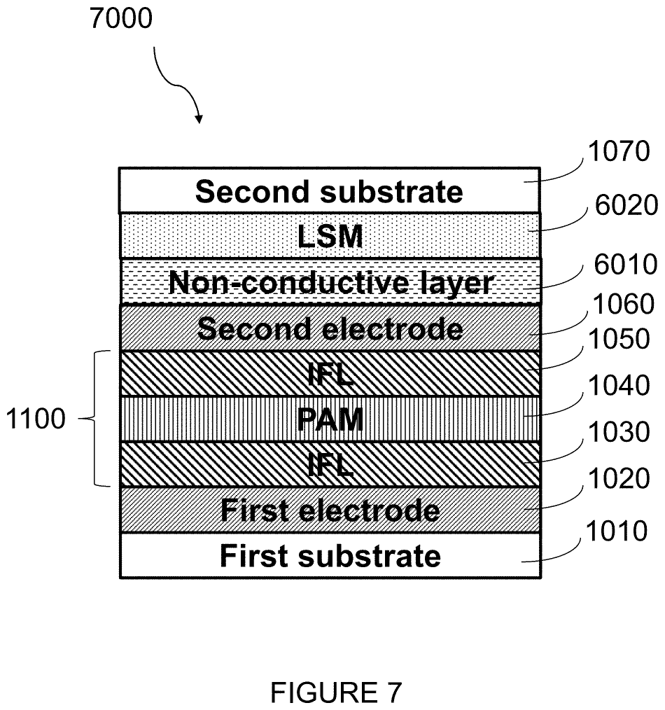

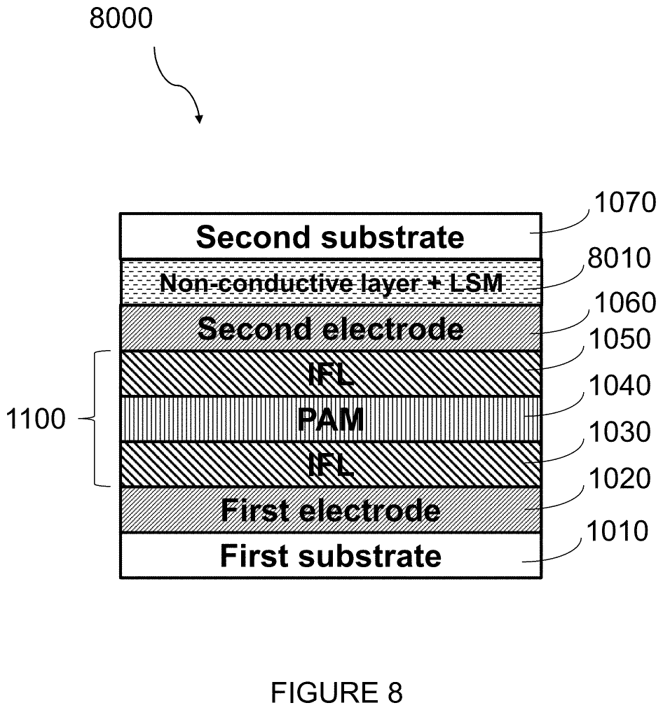

In one embodiment, a lead-sequestration material layer is deposited or applied on the back of a perovskite material device, adjacent to a non-conductive layer, or as a component of a non-conductive layer. FIGS. 6-8 are stylized diagrams of a perovskite material device according to some embodiments. In the examples depicted in FIGS. 6-8, a lead-sequestration material (LSM) is deposited or applied to the back side of the perovskite material device, adjacent to a non-conductive layer, or as a component of a non-conductive layer. As an example, FIG. 6 illustrates an embodiment of a perovskite material device 6000 having a non-conductive layer 6010 and a lead-sequestration material (LSM) layer 6020. In some embodiments, the non-conductive layer 6010 may be similar to the non-conductive layer 2380 discussed in paragraph [0087] above. In the example depicted in FIG. 6, the lead-sequestration material (LSM) layer 6020 is deposited or applied between the second electrode layer 1060 and the non-conductive layer 6010. In the example depicted in FIG. 7, the lead-sequestration material (LSM) layer 6020 is deposited or applied between the second substrate layer 1070 and the non-conductive layer 6010. In the example depicted in FIG. 8, a lead-sequestration material may be mixed with the non-conductive layer to form the combined layer 8010.

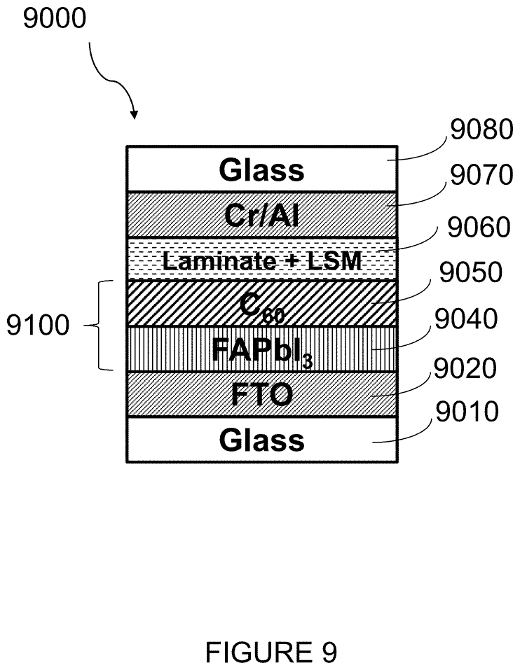

FIG. 9 depicts an example perovskite device 9000 in accordance with various embodiments. The device 9000 illustrates embodiments including first and second glass substrates 9010 and 9080. In the example depicted in FIG. 9, a first electrode (FTO) 9020 is disposed upon an inner surface of the first substrate 9010, and a second electrode 9070 is disposed on an inner surface of the second substrate 9080. Second electrode 9070 may be a chromium-aluminum bilayer (Cr/Al), wherein a layer of chromium is coated with a layer of aluminum to form the bilayer. An active layer 9100 is sandwiched between the two electrodes 9020 and 9070. The active layer 9100 includes a photoactive material (e.g., MAPbI₃, FAPbI₃) 9040, and a charge transport layer (e.g., C₆₀) 9050. A laminate layer comprising a lead-sequestration material 9060 is adjacent and contacts the inner surface of the second electrode 9070.

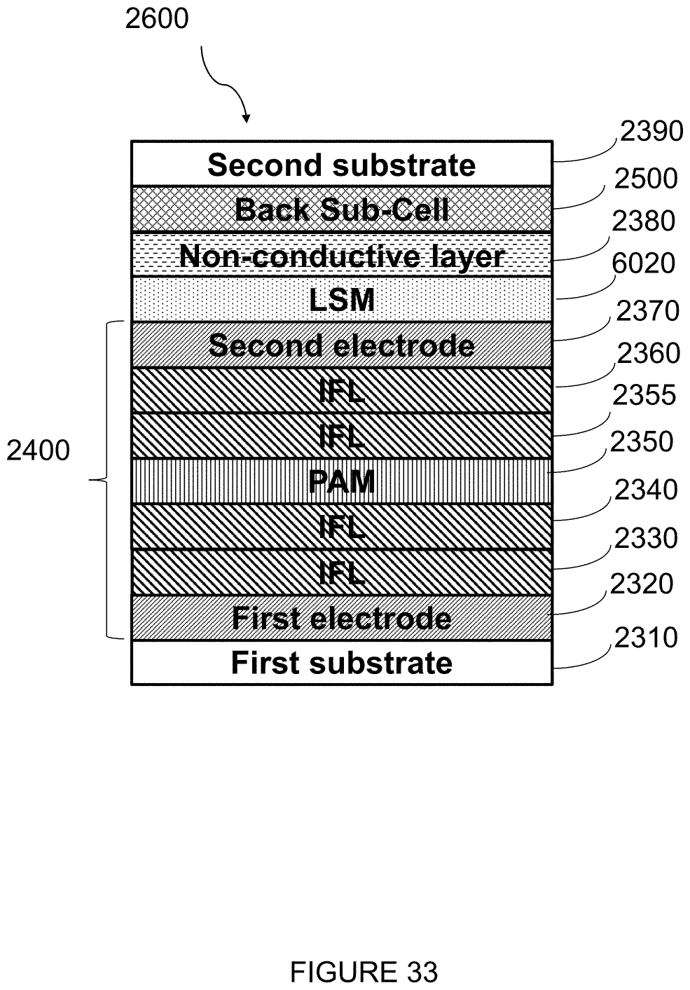

In one embodiment, a lead-sequestration material layer may be present in a four-terminal tandem PV device. FIG. 33 is a stylized diagram of a four-terminal tandem perovskite material device according to some embodiments. In the example depicted in FIG. 33, an LSM 6020 is deposited or applied to the back side of the front sub-cell 2400 (as shown), adjacent to the non-conductive layer 2380, or as a component of a non-conductive layer 2380. In certain embodiments, the LSM may be part of the back sub-cell 2500, or there may be multiple LSMs across the two sub-cells.

In some embodiments, the lead-sequestration material layer may be an anti-reflective coating. In certain embodiments, the lead-sequestration material layer may have an index of refraction of from about 1 to about 1.5. In some embodiment, the lead-sequestration material layer may have an index of refraction (n) of from about 1.2 to about 1.3. In one embodiment, for example, the lead-sequestration material layer may have an index of refraction (n) of 1.25. In certain embodiments, perovskite material devices may include one or more additional anti-reflective coatings in addition to the lead-sequestration material.

In some embodiments, the lead-sequestration material layer may be an anti-soiling layer. In certain embodiments, surface contaminants such as oils, dust, water, animal excrement, and the like may adhere less preferentially to the lead-sequestration material than the substrate surface, such as glass and polymer. In certain embodiments, the lead-sequestration material may possess hydrophobic and/or oleophobic properties. In certain embodiments, perovskite material devices may include one or more additional anti-soiling coatings in addition to the lead-sequestration material.

In certain embodiments, the lead-sequestration material layer may have a thickness of from about 1 nm to about 1 mm, 10 nm to about 500 μm, or 0.1 μm to about 200 μm.

Lead-Sequestration Material

Lead-sequestration materials suitable for certain embodiments of the present disclosure may include at least one lead-sequestration compound including one or more lead binding groups as a substituent (e.g., moiety or functional group) of the lead-sequestration compound. In some embodiments, the lead-sequestration compound may include a lead binding group with a strong affinity for Pb²⁺ ions. Examples of lead binding groups suitable for certain embodiments of the present disclosure include, but are not limited to an oxide, hydroxide, amine, amide, ammonium, carboxylate, carboxylic acid, aldehyde, ester, ether, phosphine, phosphinate, phosphonate, a carboxylate, a phosphate, a sulfide, a sulfate, and any combination thereof. Examples of lead-sequestration compounds suitable for certain embodiments of the present disclosure include, but are not limited to EDTA, organophosphates, organosulfates, thiols, thiourea carbamates, carbonates, aminos, formamidinos, and any derivative or combination thereof. In some embodiments, the lead-sequestration compound may be a monomer or a small organic molecule. In some embodiments, the lead-sequestration compound may not include a polymer or may not include an organic polymer.

In certain embodiment, the lead-sequestration material and/or the lead-sequestration compound may be insoluble in water. In some embodiments, the lead-sequestration material may comprise a lead-sequestration compound attached (e.g., bound) to a binding material that is insoluble in water. In one embodiment, a lead-sequestration material may be in the form of solid composites or solution ink that can be processed into thin films or coatings by heat extrusion, blade coating, slot-die coating, spin coating, nozzle spraying, and/or dip-casting.

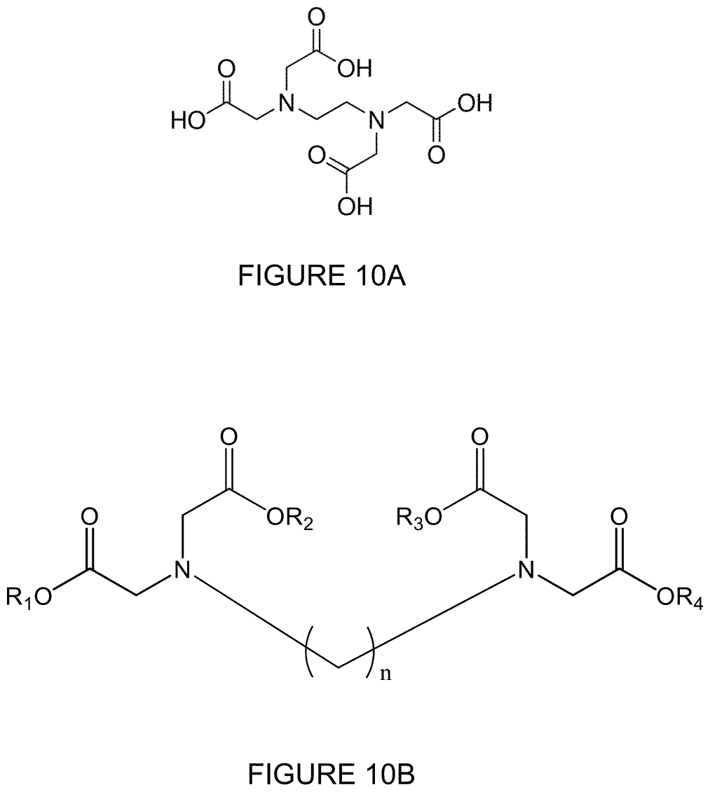

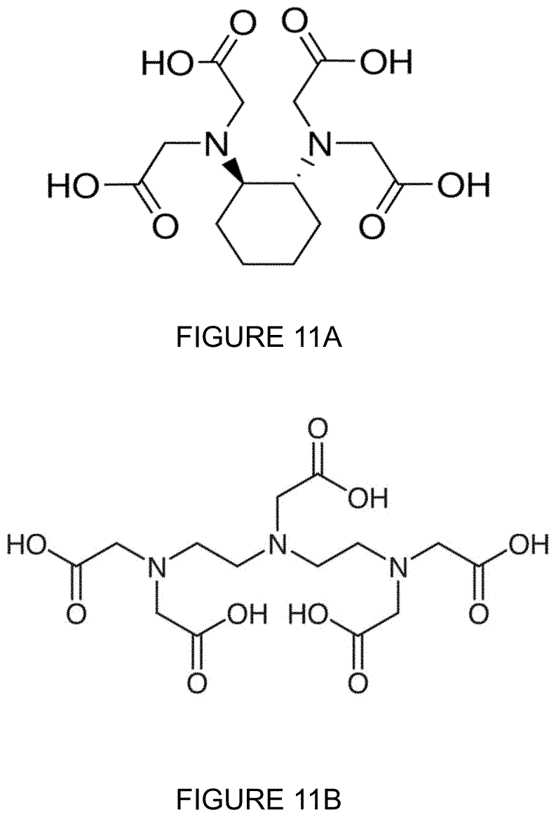

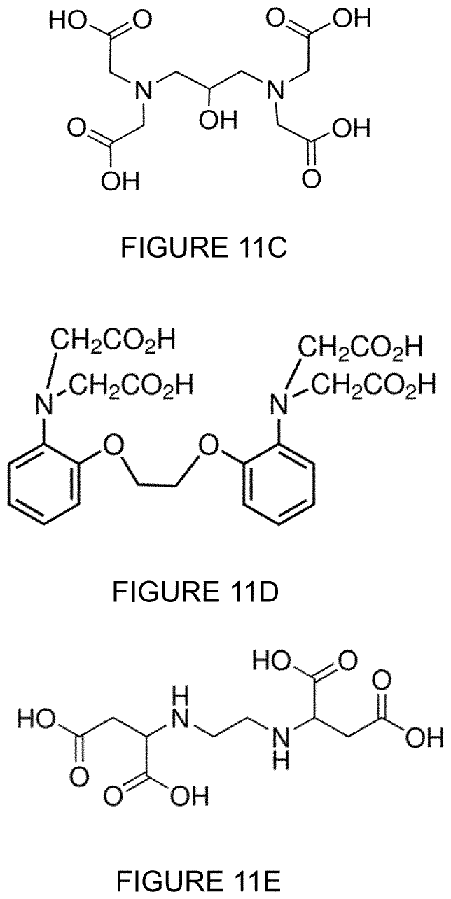

In certain embodiments, the lead-sequestration compound comprises carboxylate as a lead binding group. Examples of lead-sequestration compounds comprising carboxylate lead binding groups include, but are not limited to ethylenediaminetetraacetic acid (EDTA), an EDTA derivative, and any combination thereof. FIG. 10A illustrates the chemical structure of EDTA, and FIG. 10B illustrates the chemical formula for some example EDTA derivatives that may be used as lead-sequestration compounds in certain embodiments. With reference to the EDTA derivative structure of FIG. 10B, in certain embodiments, n may be an integer from 1 to 12 and R₁, R₂, R₃, and R₄ each may independently be H, Li, Na, K, or NH₄. In one embodiment, two or more of R₁, R₂, R₃, and R₄ may be the same, or they may each be different. FIGS. 11A-11E illustrate chemical structures of additional examples of EDTA derivatives suitable for certain embodiments.

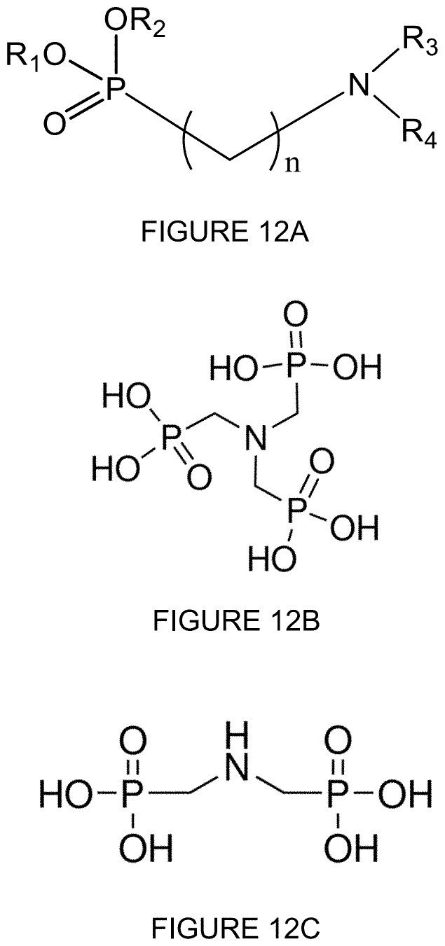

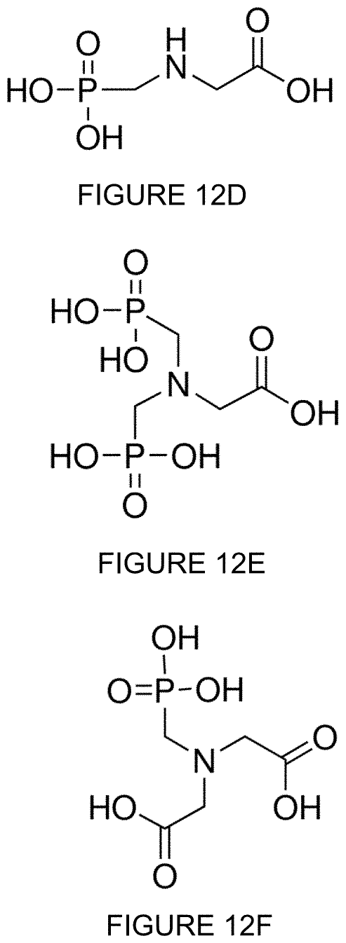

In certain embodiments, the lead-sequestration compound comprises phosphate as a lead binding group. Examples of lead-sequestration compounds comprising phosphate lead binding groups include organophosphates. FIGS. 12A-15B illustrate structures and examples of organophosphates suitable for certain embodiments. FIG. 12A illustrates a first chemical structure of organophosphates that may be used as lead-sequestration compounds according to some embodiments. With reference to the organophosphate structure of FIG. 12A, in some embodiments, n may be an integer from 1 to 12; R₁ and R₂ may each independently be H, Li, Na, K, NH₄, —CH₃, or —CH₂(CH₂)ₘ₁CH₃, where m₁ may be an integer from 0 to 10; and R₃ and R₄ may each independently be H, —(CH₂)ₘ₂—PO(OR₁)(OR₂), or —(CH₂)ₘ₃—COOR₁, where m₂ may be an integer from 1 to 6 and m₃ may be an integer from 1 to 6. In some embodiments, R₁ and R₂ may be the same or different. In certain embodiments, R₃ and R₄ may be the same or different. FIGS. 12B-12F illustrate various example molecules having of the organophosphate structure of FIG.

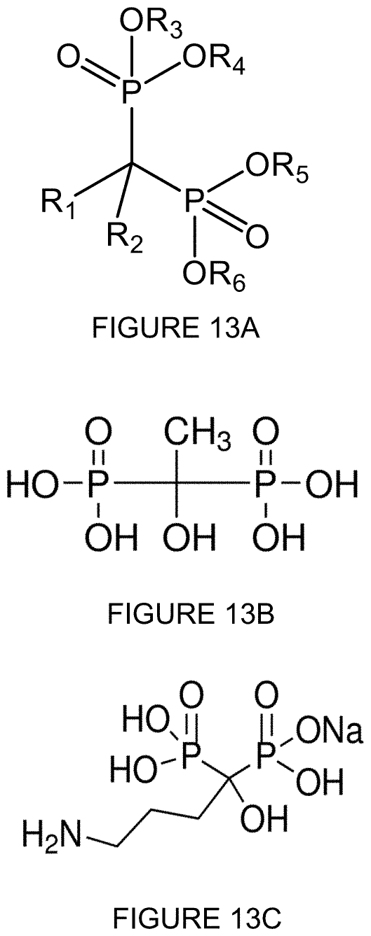

FIG. 13A illustrates a second chemical structure of organophosphates that may be used as lead-sequestration compounds according to some embodiments. In some embodiments, the organophosphate may be a phosphinate or a phosphonate. With reference to the organophosphate structure of FIG. 13A, R₁ may be H, —CH₃, —CH₂(CH₂)ₘ₁CH₃, or —CH₂(CH₂)ₘ₂NH₂, where m₁ may be an integer from 0 to 10 and m₂ may be an integer from 0 to 10; R₂ may be H, —CH₃, or —CH₂(CH₂)ₘ₃CH₃, where m₃ may be an integer from 0 to 10; and R₃, R₄, R₅, and R₆ may each independently be H, Li, Na, K, NH₄, —CH₃, or —CH₂(CH₂)ₘ₄CH₃, where m₄ may be an integer from 0 to 10. In certain embodiments, two or more of R₃, R₄, R₅, or R₆ may be the same or different. FIGS. 13B and 13C illustrate various example molecules having the organophosphate structure of FIG. 13A.

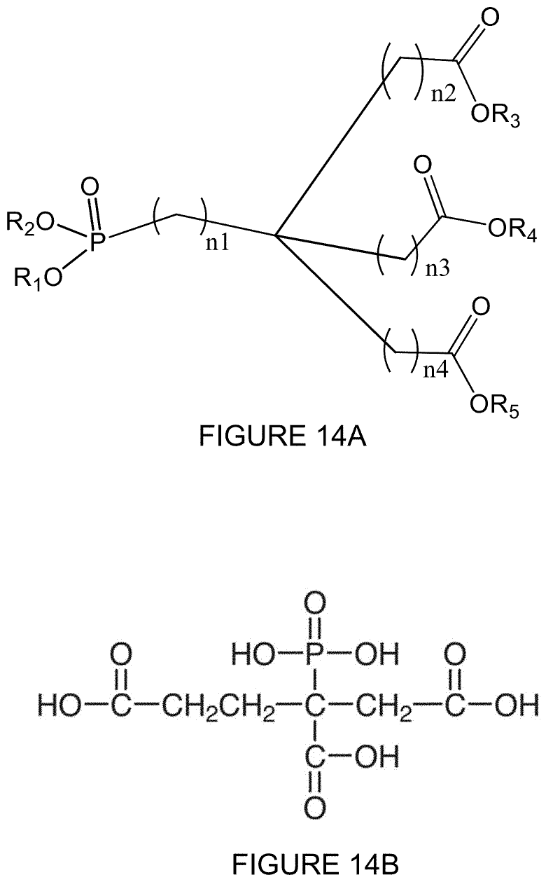

FIG. 14A illustrates a third structure of organophosphates that may be used as lead-sequestration compounds according to some embodiments. With reference to FIG. 14A, n1 may be an integer from 0 to 6; n2 may be an integer from 0 to 6; n3 may be an integer from 0 to 6; n4 may be an integer from 0 to 6; R₁ may be H, Li, Na, K, NH₄, —CH₃, or —CH₂(CH₂)ₘ₁CH₃, where m1 may be an integer from 0 to 10; R₂ may be H, Li, Na, K, NH₄, —CH₃, or —CH₂(CH₂)ₘ₂CH₃, where m2 may be an integer from 0 to 10; R₃ may be H, Li, Na, K, or NH₄; R₄ may be H, Li, Na, K, or NH₄; and R₅ may be H, Li, Na, K, or NH₄. In certain embodiments, two or more of R₁, R₂, R₃, R₄, or R₅, may be the same or different. FIG. 14B illustrates an example molecule having the organophosphate structure of FIG. 14A.

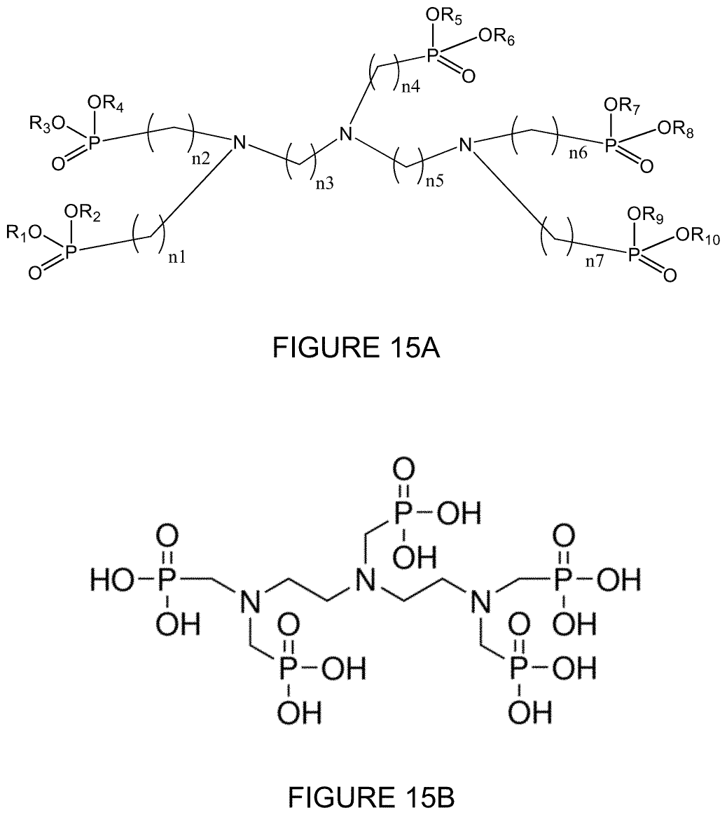

FIG. 15A illustrates a fourth structure of organophosphates that may be used as a lead-sequestration compounds according to some embodiments. With reference to FIG. 15A, n1, n2, n3, n4, n5, n6, and n7 may each independently be an integer from 0 to 6; and R₁, R₂, R₃, R₄, R₅, R₆, R₇, R₈, R₉, R₁₀ may each independently be H, Li, Na, K, NH₄, —CH₃, or —CH₂(CH₂)ₘCH₃, where m may be an integer from 0 to 10. In certain embodiments, two or more of R₁, R₂, R₃, R₄, R₅, R₆, R₇, R₈, R₉, or R₁₀ may be the same or different. FIG. 15B illustrates an example molecule with the fourth structure of organophosphate.

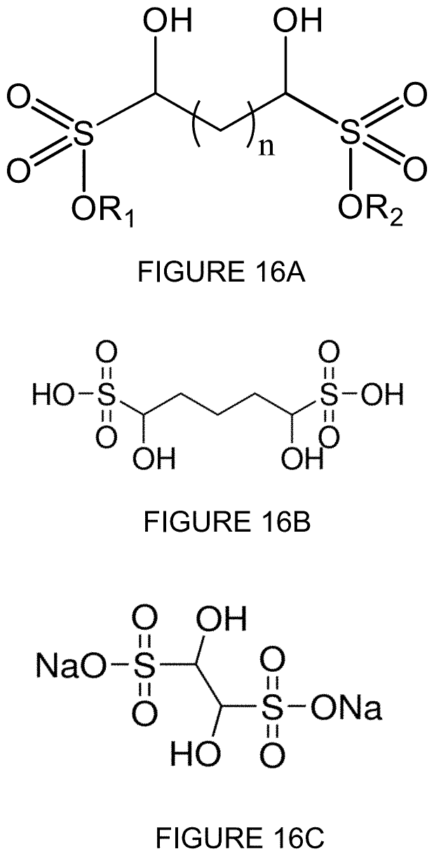

In certain embodiments, the lead-sequestration compound comprises sulfate as a lead binding group. Examples of lead-sequestration compounds comprising sulfate lead binding groups include organosulfates. FIGS. 16A-18B illustrate structures and examples of organophosphates suitable for certain embodiments. FIG. 16A illustrates a first structure of organosulfates that may be used as a lead-sequestration compound according to some embodiments. With reference to FIG. 16A, n may be an integer from 0 to 10, and R₁ and R₂ may be H, Li, Na, K, or NH₄. In certain embodiments, R₁ and R₂ may be same or different. FIGS. 16B and 16C illustrate example molecules having the organosulfate structure of FIG. 16A.

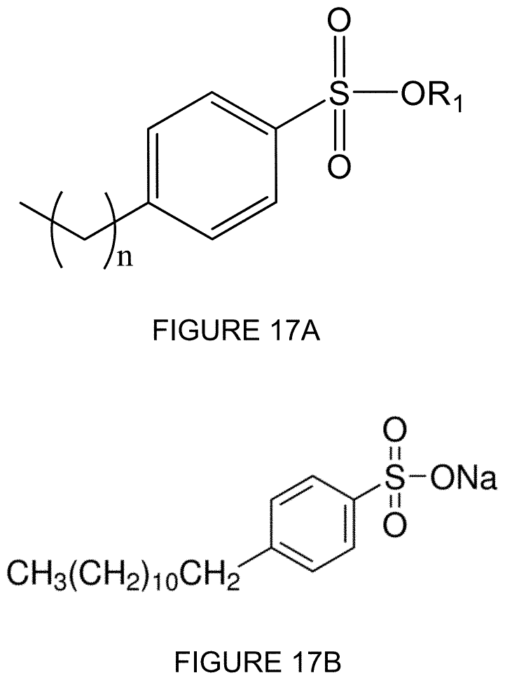

FIG. 17A illustrates a second structure of organosulfates that may be used as a lead-sequestration compound according to some embodiments. With reference to FIG. 17A, n may be an integer from 0 to 19, and R₁ may be H, Li, Na, K, or NH₄. FIG. 17B illustrates an example molecule with the organosulfate structure of FIG. 17A.

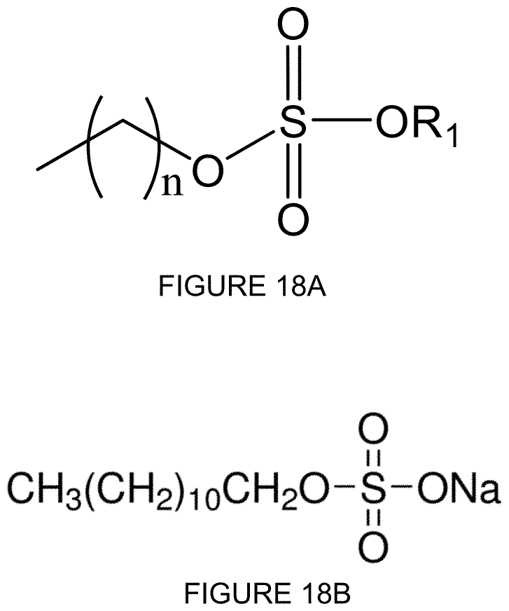

FIG. 18A illustrates a third structure of organosulfate that may be used as a lead-sequestration compound according to some embodiments. With reference to FIG. 18A, n may be an integer from 0 to 19, and R₁ may be H, Li, Na, K, or NH₄. FIG. 18B illustrates an example molecule with the organosulfate structure of FIG. 18A.

In some embodiments, the lead-sequestration material further comprises a binding material. In some examples, one or more lead-sequestration compounds (e.g., those illustrated FIGS. 12A-18B) may be attached to a binding material to form solid composites or solution inks. In certain embodiments, the binding material may be an inorganic material. In some embodiments, the solid composites or solution inks containing lead-sequestration compounds may be processed into thin film by heat extrusion, blade coating, slot-die coating, spin coating, nozzle spraying, dip-casting. In other examples, inorganic additives may be added to the solid composites or solution inks containing lead binding groups to improve films properties and/or enhance the sequestration efficiency. Examples of inorganic additives suitable for certain embodiments of the present disclosure include, but are not limited to phosphate and hydrophosphate salts, sulfate salts, carbonate salts, chromate and dichromate salts, sulfide salts, silicate salts, aluminosilicate salts of Li, Na, K, NH₄, and any combination thereof.

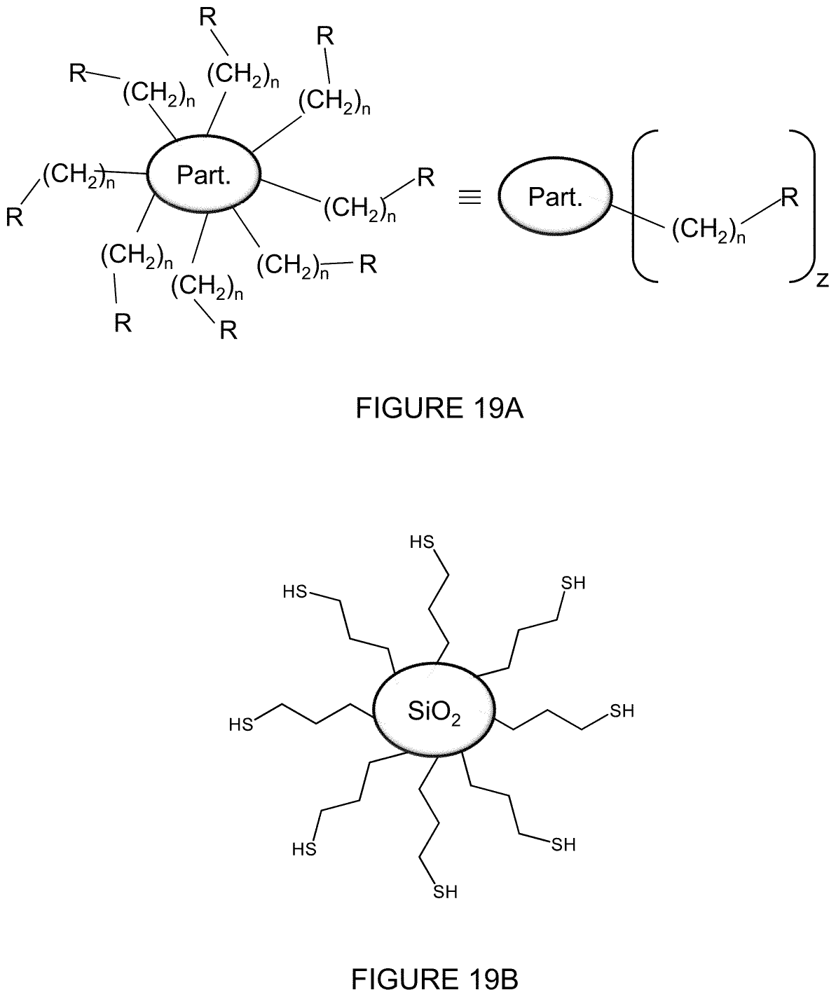

In some embodiments, the binding material to which the lead-sequestration compounds are attached is an inorganic material. In one embodiment, the inorganic material is functionalized with the lead-sequestration compounds to form a functionalized inorganic material. Examples of inorganic materials suitable for certain embodiments of the present disclosure include, but are not limited to nanoparticles, microparticles, flat surfaces, structured surfaces, mesoporous materials, covalent organic frameworks, metal organic frameworks, aerogels, and any combination thereof. FIG. 19A illustrates an example of lead-sequestration compounds attached to an inorganic particle. In the example depicted in FIG. 19A, n may be an integer from 0 to 12, z may be an integer from 1 to 10⁶ and R may be H, —SH, —NH₂, —N(CH₂COOR₁)₂, —NH(PO(OR₂)₂), —N(CH₂PO(OR₃)₂)₂, —NHCH₂CH₂SH, —NH—C(═S)—NH₂, where R₁, R₂, and R₃ may each independently be H, Li, Na, K, NH₄, —CH₃, or —CH₂(CH₂)ₘCH₃, where m is an integer from 0 to 10. As shown in FIG. 19A and in other similar figures in this disclosure, z represents the number of lead-sequestration compounds attached to the inorganic particle. In another embodiment, z may represent the molality of the lead-sequestration compounds attached to the inorganic particle. In such an embodiment, z in FIG. 19A may be from about 0.01 to about 100 mmol/g, from about 0.1 to about 10 mmol/g, or from about 0.5 to about 2.0 mmol/g.

Examples of inorganic microparticles or nanoparticles suitable for certain embodiments include, but are not limited to microparticles or nanoparticles of silica, silicates, zinc oxide, titania, vanadia, tantala, zirconia, hafnia, silicon nitride, boron nitride, and any combination thereof. In some embodiments, the size of the microparticle is from about 1 to about 1,000 microns. In other embodiments, the size of the nanoparticle is from about 1 to about 1,000 nm. In some embodiments, the shape of the microparticle or the nanoparticle is spherical, oval, rod-shaped, cubic, hexagonal, triangular, star-shaped, prism-shaped, plate-shaped, flower-shaped, or bar-shaped. In one embodiment, the microparticle and nanoparticle is non-porous, microporous (pore size up to 2 nm), mesoporous (pore size 2-50 nm), or macroporous (pore size from 50 nm to 75 microns). FIG. 19B illustrates an example of FIG. 19A with lead-sequestration compounds attached to an SiO₂ particle. In one embodiment, the SiO₂ particle is a microparticle. In another embodiment, the SiO₂ particle is a nanoparticle.

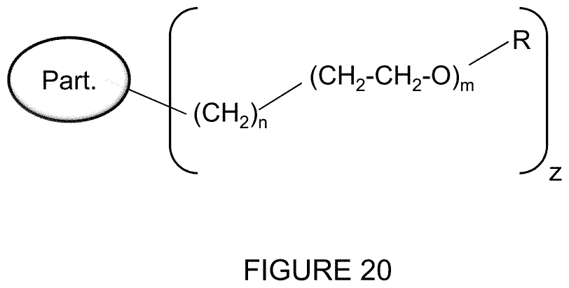

FIG. 20 illustrates another example of a lead-sequestration compound attached to an inorganic particle. In the example depicted in FIG. 20, n may be an integer from 0 to 4; m may be an integer from 0 to 6, z may be an integer from 1 to 10⁶ and R may be H, —SH, —NH₂, —N(CH₂COOR₁)₂, —NH(PO(OR₂)₂), —N(CH₂PO(OR₃)₂)₂, —NHCH₂CH₂SH, or —NH—C(═S)—NH₂, where R₁, R₂, and R₃ may each independently be H, Li, Na, K, NH₄, —CH₃, —CH₂(CH₂)ₘCH₃ wherein m may be an integer from 0 to 10. In another embodiment, z in FIG. 20 may represent a molality of from about 0.01 to about 100 mmol/g, from about 0.1 to about 10 mmol/g, or from about 0.5 to about 2.0 mmol/g. The shape and size of the particle in FIG. 20 is similar to the particles discussed above.

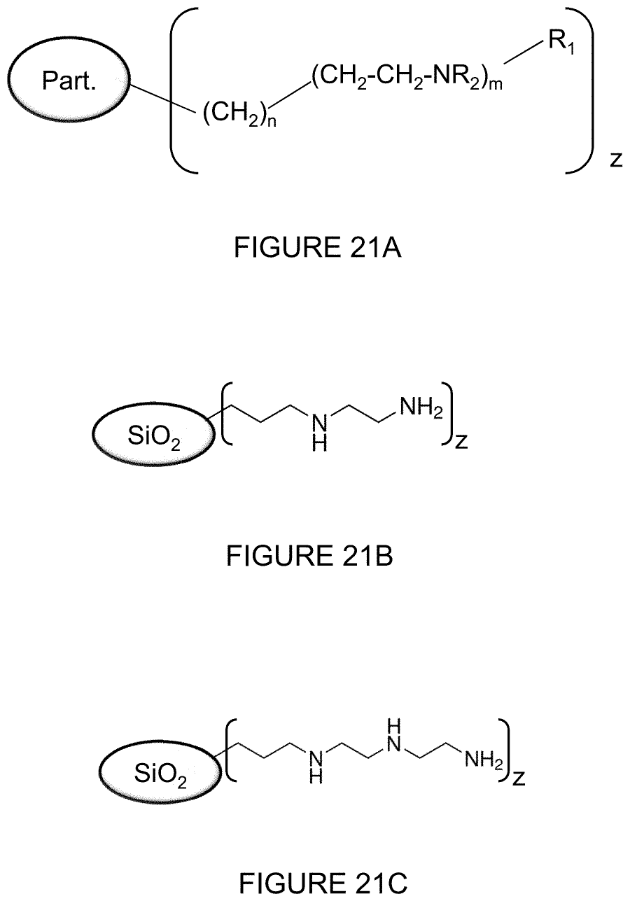

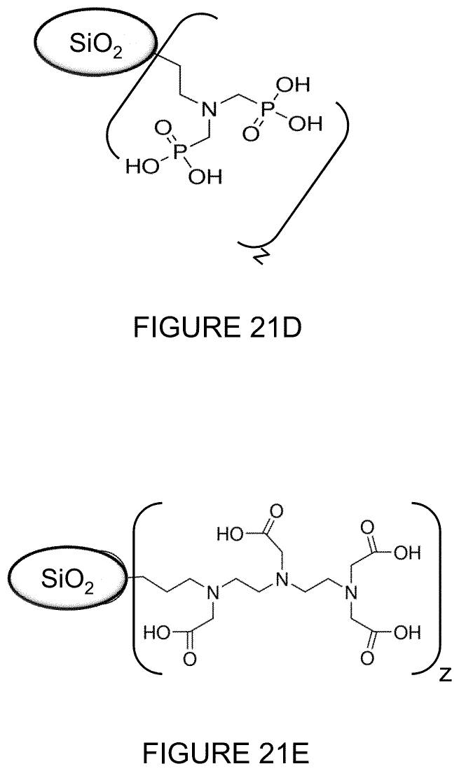

FIG. 21A illustrates another example of lead-sequestration compounds attached to an inorganic particle. With reference to FIG. 21A, n may be an integer from 0 to 4; m may be an integer from 0 to 6, z may be an integer from 1 to 10⁶; R₁ may be H, —SH, —NH₂, —N(CH₂COOR₃)₂, —NH(PO(OR₄)₂), —N(CH₂PO(OR₅)₂)₂, —NHCH₂CH₂SH, —NH—C(═S)—NH₂; R₃₋₅ may be H, Li, Na, K, NH₄, —CH₃, or —CH₂(CH₂)ₘ₂CH₃, where m2 may be an integer from 0 to 10; R₂ may be the same as or R₁ or may be H, —SH, —NH₂, —N(CH₂COOR₃)₂, —NH(PO(OR₄)₂), —N(CH₂PO(OR₅)₂)₂, —NHCH₂CH₂SH, or —NH—C(═S)—NH₂; and R₃, R₄, and R₅ may each independently be H, Li, Na, K, NH₄, —CH₃, -or CH₂(CH₂)ₘ₂CH₃, where m2 may be an integer from 0 to 10. In another embodiment, z in FIG. 21A may represent a molality of from about 0.01 to about 100 mmol/g, from about 0.1 to about 10 mmol/g, or from about 0.5 to about 2.0 mmol/g. The shape and size of the particle in FIG. 21A is similar to the particle discussed in FIG. 19A.

FIGS. 21B-21E illustrate various examples of FIG. 21A with lead-sequestration compounds attached to SiO₂ particles, where z may be an integer from 1 to 10⁶ or z may represent a molality of from about 0.01 to about 100 mmol/g, from about 0.1 to about 10 mmol/g, or from about 0.5 to about 2.0 mmol/g. In one embodiment, the SiO₂ particle is microparticle. In another embodiment, the SiO₂ particle is nanoparticle.

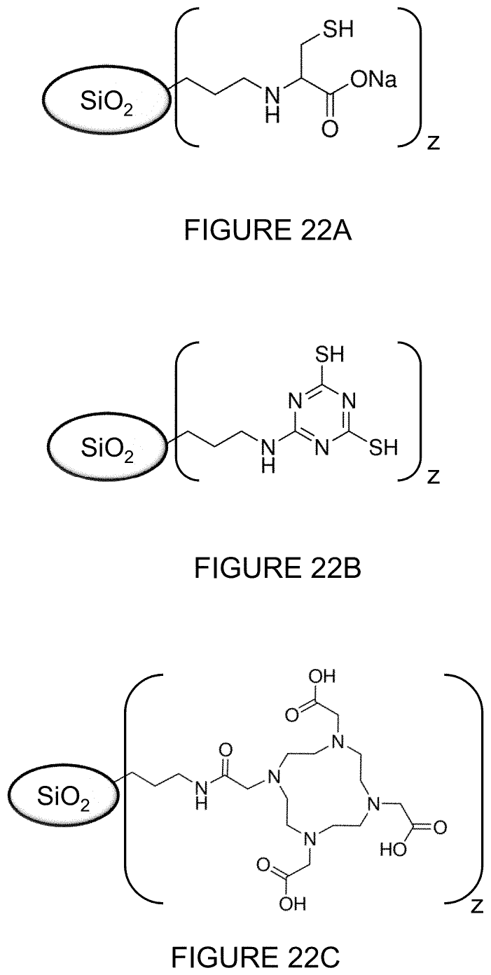

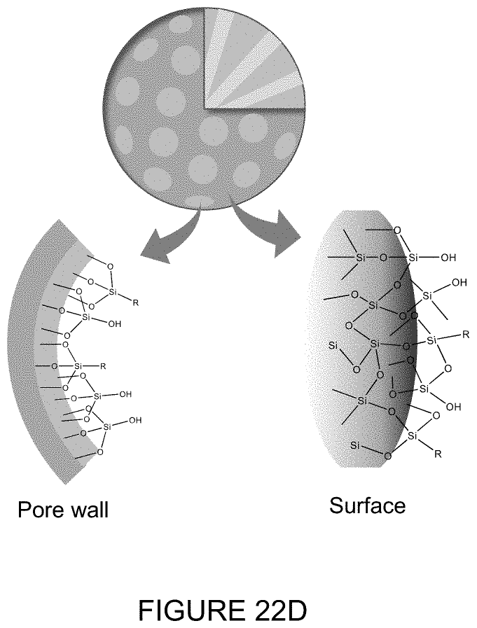

FIGS. 22A-22C illustrate various examples of lead-sequestration compounds attached to silica gels to form functionalized silica gels. In the examples depicted in FIGS. 22A-22C, z may be an integer from 1 to 10⁶. In another embodiment, z in FIGS. 22A-C may represent a molality of from about 0.01 to about 100 mmol/g, from about 0.1 to about 10 mmol/g, or from about 0.5 to about 2.0 mmol/g. The size and shape of the SiO₂ particles is similar to the particle discussed in FIG. 19A. FIG. 22D illustrates an example of lead-sequestration compounds being attached to a mesoporous silica gel.

In some embodiments, the lead-sequestration compounds may be attached (e.g., bound) to a polymeric material. In certain embodiments, the polymeric material such as a polymer, resin, elastomer, or thermoset. In some embodiments, the polymeric material may include poly vinyl acetate, polyolefins, polystyrenes, polyglycols, polyorganic acids, natural rubber, synthetic rubber, polyesters, nylons, polyamides, polyaryls, polynucleic acids, polysaccharides, polyurethanes, acrylonitrile butadiene styrene, acrylic, acrylic polymers, acrylic resins, cross-linked porous resins, and any combination or derivative thereof. Examples of polymers suitable for certain embodiments include, but are not limited to poly(ethylene-vinyl acetate) (EVA), high-density polyethylene (HDPE), low-density polyethylene (LDPE), polypropylene (PP), polystyrene (PS), polyethylene glycol (PEG/PEO), poly(methyl methacrylate) (PMMA), polyoxymethylene (POM), poly(acrylonitrile butadiene styrene) (ABS), polyphenylene sulfide (PPS), polytetrafluoroethylene (PTFE), polyvinylidene difluoride (PVDF), polyvinyl chloride (PVC), poly(ethylene terephthalate (PET), polylactic acid (PLA), polycarbonate (PC), polyether ether ketone (PEEK), polybutylene terephthalate (PBT), butylene rubber, polyisoprene, polyurethane (PU), polydimethylsiloxane (PDMS), urea formaldehyde resin, an epoxy resin, phenol formaldehyde resin (PF), derivatives thereof, and any combination thereof. The configuration of the polymer backbone of the binding polymers may be isotactic, syndiotactic, or atactic. In some embodiments, the functionalized inorganic materials comprising one or more lead-sequestration compounds may be incorporated into polymeric materials such as polymers, resins, elastomers, and thermosets to form a composite material. In certain embodiments, lead-sequestration compounds may be covalently bound as a substituent or pendent group of a polymeric material.

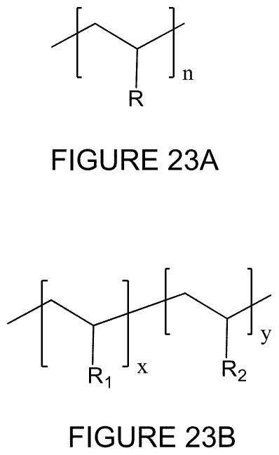

FIGS. 23A and 23B illustrate examples of polyvinyl-backbone polymers suitable as polymeric material in certain embodiments. In the example depicted in FIG. 23A, n may be an integer from 1 to 20 or from 1 to 6 and R may be H, —SH, —NH₂, —N(CH₂COOR₃)₂, —NH(PO(OR₄)₂), —N(CH₂PO(OR₅)₂)₂, —NHCH₂CH₂SH, or —NH—C(═S)—NH₂, where R₃, R₄, and R₅ may be H, Li, Na, K, NH₄, —CH₃, or —CH₂(CH₂)ₘCH₃, and where m may be an integer from 0 to 10. In the example depicted in FIG. 23B, x and y may independently be integers from 1 to 20 or from 1 to 6; R₁ may be H, —SH, —NH₂, —N(CH₂COOR₃)₂, —NH(PO(OR₄)₂), —N(CH₂PO(OR₅)₂)₂, —NHCH₂CH₂SH, or —NH—C(═S)—NH₂, where R₃, R₄, and R₅ may each independently be H, Li, Na, K, NH₄, —CH₃, or —CH₂(CH₂)ₘCH₃ and where m may be an integer from 0 to 10; and R₂ may be R₁, H, —SH, —NH₂, —N(CH₂COOR₃)₂, —NH(PO(OR₄)₂), —N(CH₂PO(OR₅)₂)₂, —NHCH₂CH₂SH, or —NH—C(═S)—NH₂, where R₃, R₄, and R₅ may be H, Li, Na, K, NH₄, —CH₃, or —CH₂(CH₂)ₘCH₃ and where m may be an integer from 0 to 10.

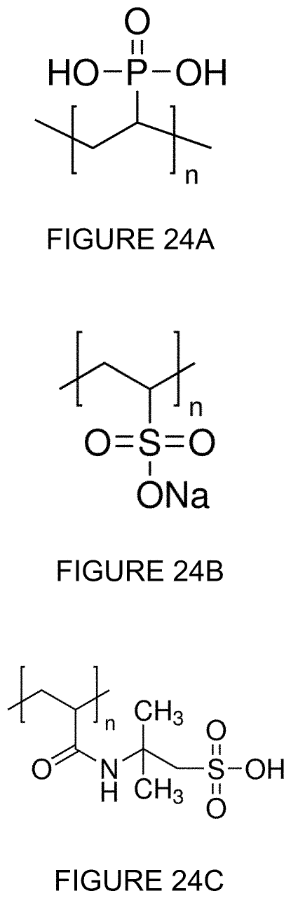

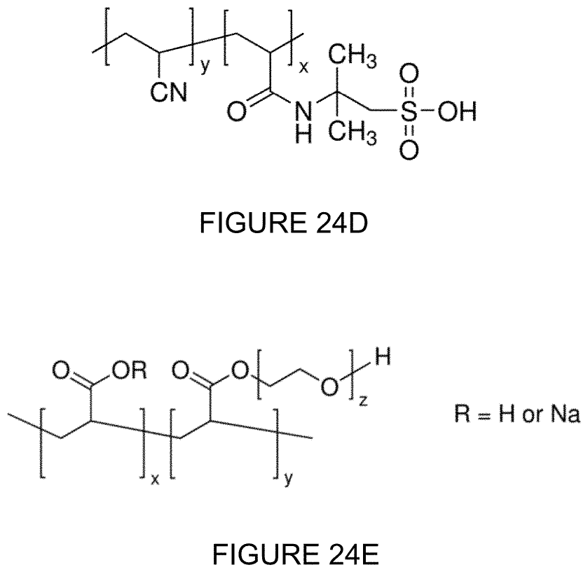

FIGS. 24A-24E illustrate various examples of lead-sequestration compounds attached to polyvinyl-backbone polymers. In the examples depicted in FIGS. 24A-C, n may be an integer from 1 to 20 or from 1 to 6. In the examples depicted in FIGS. 24D and 24E, x and y may independently be integers from 1 to 20 or from 1 to 6, and z may be an integer from 1 to 10⁶. In another embodiment, z in FIG. 24E may represent a molality of from about 0.01 to about 100 mmol/g, from about 0.1 to about 10 mmol/g, or from about 0.5 to about 2.0 mmol/g.

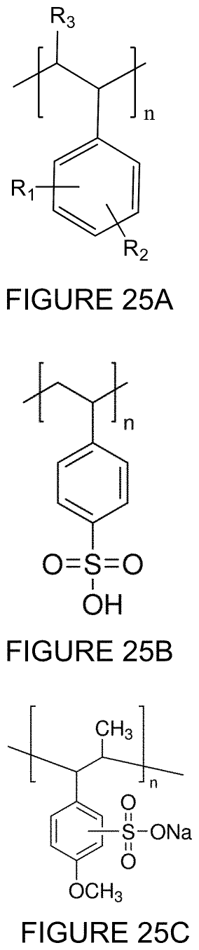

FIG. 25A illustrates a first structure of polystyrene derivative-backbone polymers that lead-sequestration compounds may be attached to. With reference to FIG. 25A, n may be an integer from 1 to 20 or from 1 to 6; R₁ may be —SO₃R₄ or —CH₂—N(CH₂COOR₅)₂; R₂ may be —CH₃ or —OCH₃; R₃ may be H or —CH₃; R₄ may be H, Li, Na, K, or NH₄; and R₅ may be H, Li, Na, K, or NH₄. Furthermore, R₁, R₂ can be at ortho-, meta-, or para-position relative to the polymer chain. FIGS. 25B and 25C illustrate two examples of lead-sequestration compounds attached to polystyrene derivative-backbone polymers. For those compounds, n may be an integer from 1 to 20 or from 1 to 6.

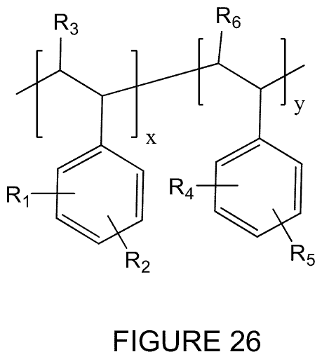

FIG. 26 illustrates a second structure of polystyrene derivative-backbone polymers that lead binding groups may be attached to. In the example depicted in FIG. 26, x and y may independently be integers from 1 to 20 or from 1 to 6; R₁ may be —SO₃R₇, or —CH₂—N(CH₂COOR₈)₂; R₇ may be H, Li, Na, K, or NH₄; R₈ may be H, Li, Na, K, or NH₄; R₂ may be —CH₃ or —OCH₃; R₃ may be —H or —CH₃; R₄ may be —SO₃R₉ or —CH₂—N(CH₂COOR₁₀)₂; R₉ may be H, Li, Na, K, or NH₄; R₁₀ may be H, Li, Na, K, or NH₄; R₅ may be —CH₃ or —OCH₃; R₆ may be H or —CH₃. In addition, R₁, R₂, R₃, R₄ can be at ortho-, meta-, or para-position relative to the polymer chain.

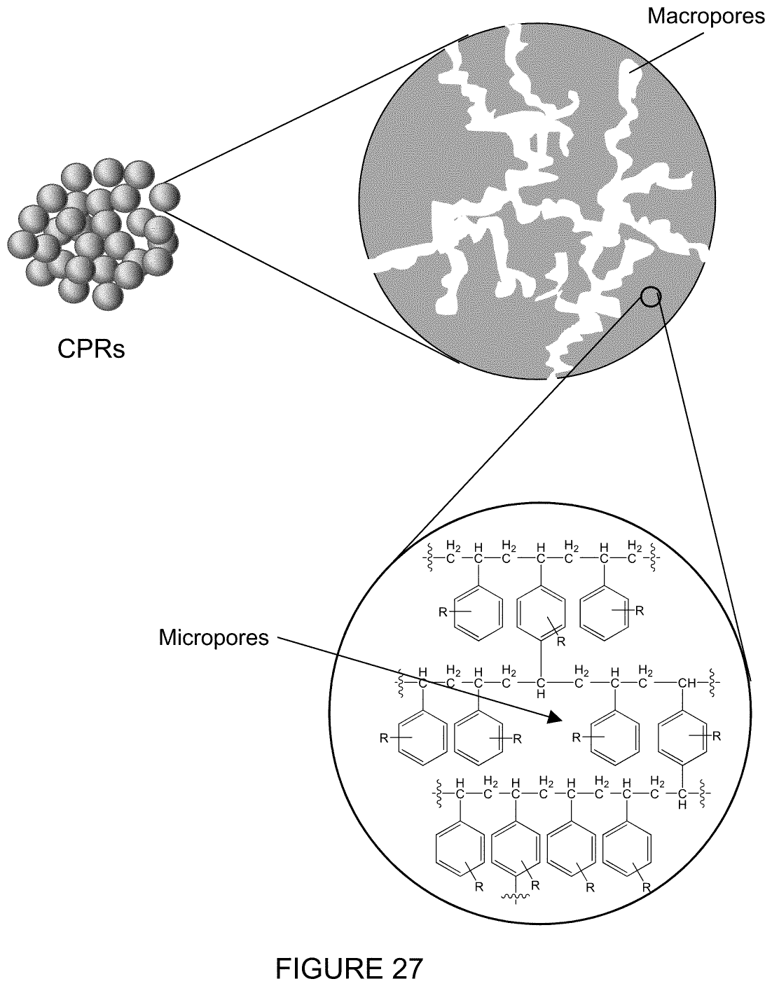

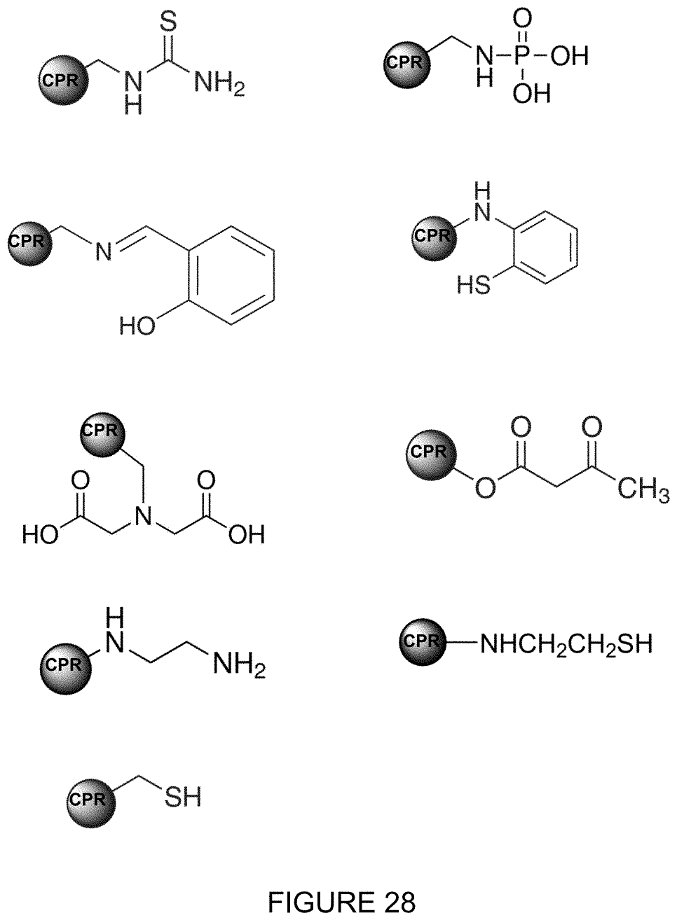

In some embodiments, the lead-sequestration compounds may be attached to cross-linked polymeric resins. FIG. 27 is a schematic illustration of the structure of cross-linked porous resins (CPRs) that lead-sequestration compounds may be attached to. In the example depicted in FIG. 27, R may be —SH, —NH₂, —N(CH₂COOR₁)₂, —NH(PO(OR₂)₂), —N(CH₂PO(OR₃)₂)₂, —NHCH₂CH₂SR₄, —SO₃R₅, or —NH—C(—S)—NH₂, where R₁, R₂, R₃, R₄, and R₅ may each independently be H, Li, Na, K, or NH₄. In one embodiment, the resins may be based on polystyrene backbone crosslinked with divinylbenzene. In one example, the resin size is between 1 to 1,000 microns. In another example, the shape of the resins is spherical, oval, rod-shaped, cubic, hexagonal, triangular, star-shaped, prism-shaped, plate-shaped, bar-shaped, flower-like, and any combination thereof. As depicted in FIG. 27, the CPRs may comprise a macroporous structure comprising microporous crosslinked polymers. FIG. 28 illustrate various examples lead binding molecule attached to CPRs illustrated in FIG. 27.

Numerous modifications, alterations, and changes to the described embodiments are possible without departing from the scope of the present invention defined in the claims. It is intended that the present invention not be limited to the described embodiments, but that it has the full scope defined by the language of the following claims, and equivalents thereof.

What is claimed is:

1. A perovskite material device comprising:
a lead-sequestration compound comprising one or more lead binding groups selected from the group consisting of: a carboxylate, a phosphate, a sulfide, a sulfate, and any combination thereof.

2. The perovskite material device of claim 1, wherein the lead-sequestration compound is ethylenediaminetetraacetic acid (EDTA) or an EDTA derivative.

3. The perovskite material device of claim 1, wherein the lead-sequestration compound is an organophosphate.

4. The perovskite material device of claim 1, wherein the lead-sequestration compound is an organosulfate.

5. The perovskite material device of claim 1, wherein the lead-sequestration compound is attached to a binding material that is insoluble in water.

6. The perovskite material device of claim 5, wherein the binding material is selected from the group consisting of: a nanoparticle, a microparticle, a flat surface, a structured surface, a mesoporous material, a covalent organic framework, a metal organic framework, an aerogel, and any combination thereof.

7. The perovskite material device of claim 5, wherein the binding material and the lead-sequestration compound form a solid composite.

8. The perovskite material device of claim 5, wherein a composition of the binding material comprises silica, silicates, zinc oxide, titania, vanadia, tantala, zirconia, hafnia, silicon nitride, or boron nitride.

9. The perovskite material device of claim 5, wherein the binding material is a microparticle or nanoparticle and the shape of the binding material is spherical, oval, rod-shaped, cubic, hexagonal, triangular, star-shaped, prism-shaped, plate-shaped, or bar-shaped.

10. The perovskite material device of claim 9, wherein a size of the microparticle is from about 1 to about 1,000 microns.

11. The perovskite material device of claim 9, wherein a size of the nanoparticle is from about 1 to about 1,000 nm.

12. The perovskite material device of claim 1, wherein the lead-sequestration compound is bonded to a polymeric material selected from the group consisting of: a polymer, a resin, an elastomer, a thermoset, and any combination thereof.

13. The perovskite material device of claim 12, wherein the polymeric material is selected from the group consisting of: a polyolefin, a polystyrene, a polyglycol, a polyorganic acid, a natural rubber, a synthetic rubber, a polyester, a nylon, a polyamide, a polyaryl, a polynucleic acid, a polysaccharide, a polyurethane, an acrylonitrile butadiene styrene, an acrylic, an acrylic polymer, an acrylic resin, a cross-linked porous resin, and any combination thereof.

14. The perovskite material device of claim 7, wherein the composite further comprises one or more inorganic additives selected from the group consisting of: a phosphate salts, hydrophosphate salts, sulfate salts, carbonate salts, chromate salt, and dichromate salts, sulfide salts, silicate salts, aluminosilicate salts of Li, Na, K, NH₄, and any combination thereof.

15. The perovskite material device of claim 1, wherein the lead-sequestration material is an anti-reflective coating.

16. A method comprising:
preparing a substrate;
depositing a precursor ink comprising a lead-sequestration material onto the substrate, wherein the lead-sequestration material comprises:
a lead-sequestration compound comprising one or more lead binding groups selected from the group consisting of: a carboxylate, a phosphate, a sulfide, a sulfate, and any combination thereof, and
a binding material; and
drying the lead-sequestration precursor ink to form a lead-sequestration material layer.

17. A composition comprising:
a binding material; and
a lead-sequestration compound attached to the binding material, the lead-sequestration compound comprising one or more lead binding groups selected from the group consisting of: a carboxylate, a phosphate, a sulfide, a sulfate, and any combination thereof, wherein the binding material is selected from the group consisting of: a nanoparticle, a microparticle, a flat surface, a structured surface, a mesoporous material, a covalent organic framework, a metal organic framework, an aerogel, and any combination thereof.

18. The composition of claim 17, wherein the lead-sequestration compound is ethylenediaminetetraacetic acid (EDTA) or an EDTA derivative.

19. The composition of claim 17, wherein the lead-sequestration compound is an organophosphate.

20. The composition of claim 17, wherein the lead-sequestration compound is an organosulfate.
